(19) United States
(12) Patent Application Publication
(10) Pub. No.: US 2007/0146020 A1
(43) Pub. Date: Jun. 28, 2007

(54) High Frequency Power MESFET Gate Drive Circuits

(75) Inventor: Richard K. Williams, Sunnyvale, CA (US)

Correspondence Address: ADVANCED ANALOGIC TECHNOLOGIES, 830 EAST ARQUES AVE, SUNNYVALE, CA, 94085, US

(73) Assignee: ADVANCED ANALOGIC TECHNOLOGIES, INC, Sunnyvale, CA (US)

(21) Appl. No.: 11/307,199

(22) Filed: Jan. 26, 2006

Related U.S. Application Data
(60) Provisional application No. 60/597,406, filed on Nov. 29, 2005.

(51) Int. Cl. H03B 1/00

(52) U.S. Cl. 327/110

(57) ABSTRACT

A series of gate drive circuits for MESFETs are provided. The gate drive circuits are intended to be used in switching regulators where at least one switching device is an N-channel MESFET. For regulators of this type, the gate drive circuits provide gate drive at the correct voltage to ensure that MESFETs are neither under driven (resulting in incorrect circuit operation) nor over driven (resulting in MESFET damage or excess current or power loss).

### RELATED APPLICATIONS

This application is one of a group of concurrently filed applications that include related subject matter. The six titles in the group are: 1) High Frequency Power MESFET Gate Drive Circuits, 2) High-Frequency Power MESFET Boost Switching Power Supply, 3) Rugged MESFET for Power Applications, 4) Merged and Isolated Power MESFET Devices, 5) High-Frequency Power MESFET Buck Switching Power Supply, and 6) Power MESFET Rectifier. Each of these documents incorporates all of the others by reference.

### BACKGROUND OF INVENTION

Voltage regulators are used commonly used in battery powered electronics to eliminate voltage variations resulting from the discharging of the battery and to supply power at the appropriate voltages to various microelectronic components such as digital ICs, semiconductor memory, display modules, hard disk drives, RF circuitry, microprocessors, digital signal processors and analog ICs. Since the DC input voltage must be stepped-up to a higher DC voltage, or stepped down to a lower DC voltage, such regulators are referred to as DC-to-DC converters.

Step-down converters are used whenever a battery's voltage is greater than the desired load voltage. Conversely, step-up converters, commonly referred to boost converters, are needed whenever a battery's voltage is lower than the voltage needed to power its load. Step-down converters include transistor current source methods called linear regulators, switched capacitor networks called charge pumps, or by circuit methods where current in an inductor is constantly switched in a controlled manner. Boost converters may be also be made from charge pump switched-capacitor networks or by switched inductor techniques. Switched inductor power voltage regulators and converters are commonly referred to as “switching converters”, “switch-mode power supplies”, or as “switching regulators”. Step-down switching converters using simple inductors, rather than transformers, are also referred to as Buck converters.

Trade-offs in Switching Regulators

In either step-up or step-down DC to DC switching converters, one or more power switch elements are required to control the current and energy flow in the converter circuitry. During operation these power devices act as power switches toggling on and off at high frequencies and with varying frequency or duration. During such operation, these power devices lose energy to self heating, both during periods of on-state conduction and during the act of switching. These switching and conduction losses adversely limit the power converter's efficiency, potentially create the need for cooling the power devices, and in battery powered applications shorten battery life.

Using today's conventional power transistors as power switching devices in switching regulator circuits, an unfavorable tradeoff exists between minimizing conduction losses and minimizing switching losses. State-of-the-art power devices used in switching power supplies today primarily comprise various forms of lateral and vertical metal-oxide-semiconductor silicon field-effect-transistors or “power MOSFETs”, including submicron MOSFETs scaled to large areas, vertical current flow double-diffused “DMOS” transistors, and vertical trench-gated versions of such DMOS transistors known as “trench FETs” or “trench DMOS” transistors.

Circuit and device operation at higher frequency, desirable to reduce the size of a converter's passive components (such as capacitors and inductors) and to improve transient regulation, involve compromises in choosing the right size power device. Larger lower resistance transistors exhibit less conduction losses, but manifest higher capacitance and increased switching losses. Smaller devices exhibit less switching related losses but have higher resistances and increased conduction losses. At higher switching frequencies this trade-off becomes increasingly more difficult to manage, especially for today's power MOSFET devices, where device and converter performance and efficiency must be compromised to achieve higher frequency operation. Transistor operation at high frequency becomes especially problematic for converters operating at high input voltages (e.g. above 7V) and those operating at extremely low voltages (e.g. below 1.2 volts). In such applications, optimization of the power device involves even a stricter compromise between resistance and capacitive losses, offering narrower range of possible solutions.

Conventional Prior-Art DC/DC Converters

FIG. 1 describes a prior art boost-type DC/DC converter used to step-up and produce a higher-voltage regulated output (such as 3.3 volts) from a time varying DC input (such as a 1 V NiMH battery). In such switching regulators, the on-time of a power switch is constantly adjusted to regulate the output voltage of the converter despite variations in load current or battery voltage. In fixed frequency converters, the on-time is adjusted by varying, i.e. modulating, the power switch's pulse width. Such converters are referred to as pulse width modulation (PWM) control. PWM controllers are easily modified to operate at variable frequencies, or to switch between fixed and variable modes automatically during low-current load conditions.

In the prior-art embodiment of boost converter shown in circuit 1, the output of PWM control circuit 2 drives gate-buffer 3 which in turn drives the input of N-channel power MOSFET 4. The drain of N-channel MOSFET 4, switched at a high-frequency (typically at 700 kHz or more) controls the average current through inductor 6. Because the inductor forces voltage Vx positive whenever current is interrupted in MOSFET switch 4, the drain of N-channel MOSFET 4 remains more positive than ground, reverse biasing diode 5, so no diode current flows (other than off-state leakage current). Diode 5 is a PN junction diode intrinsic to power MOSFET 4 antiparallel to the transistor's drain and source terminals, and not an added circuit component. The term “antiparallel” means electrically connected in parallel but in a polarity opposite the normal bias of the transistor, i.e. where under normal biasing the diode remains reverse biased and off. The drain of N-channel MOSFET 4 is also connected to the output through rectifier diode 7. Whenever the voltage at Vx exceeds Vout, Schottky diode 7 forward-biases and transfers charge to output capacitor 8, boosting the output voltage above the battery voltage.

PWM control 2 and Buffer 3 are powered by voltage select circuit 9 comprising Schottky diodes 10 and 11 which acting as a double-throw switch, selects between the battery voltage and the output voltage, whichever is higher. Thus the gate drive for MOSFET switch 4 is powered from the highest possible voltage, i.e. the output voltage, except during the time the converter starts up. Other circuit methods exist to implement the power selector function 9, shown here only as an example. For example, MOSFET or bipolar transistors may be used to perform the power source selector function with less voltage drop than the Schottky diode. Alternatively, the circuitry can be permanently powered by the battery input voltage.

During converter operation, feedback from the output of the converter is used to vary the pulse width produced of PWM control circuit 2 to hold the output voltage constant under varying conditions of battery voltage and load current. Capacitor 8 filters high frequency switching noise out of the converter.

Converter 1 suffers from several major deficiencies. The biggest problem with this converter design is that a large low-resistance power MOSFET does not make a good switch, especially when powered by a gate drive of only 1 volt. For alkaline and NiMH batteries the minimum voltage condition fully discharged is actually 0.9V, making it even harder to adequately switch “on” the power MOSFET. To make the MOSFET switch large enough to exhibit a low on-resistance with so little gate drive requires a very large device having large capacitance and excessive switching losses associated with driving its gate at high frequencies.

Power selector 9 is an attempt to minimize this problem by powering gate drive for MOSFET 4 off of the converter's output after startup. Since Vout is typically 3V or more, it is more suitable to provide sufficient gate drive to the MOSFET. The disadvantage with this approach is the converter suffers lower efficiency. This fact can be understood by recognizing that the converter does not pass all the battery's energy to its output to power its load. Some current is lost to ground and some energy is lost to heat.

Depending on the operating current, the maximum current capability of the converter, the MOSFET size, and the switching frequency, converter efficiencies may be a low as 60% and rarely exceed 85%. If the gate drive current, which may be substantial when driving larger power MOSFETs, is powered from the output, the input power to the gate drive already involves additional efficiency loss (compared to powering the switch directly from the battery). The result is that powering the MOSFET from the output is less efficient than the efficiency achievable if an ideal switch driven from a 1 V input existed. Unfortunately, conventional silicon MOSFETs do not make good power switches in applications with only one volt of available gate drive.

The limitations of conventional silicon MOSFETs are illustrated in the electrical characteristics of FIG. 2 shown for a variety of on and off conditions. FIG. 2A illustrates the “family of curves” for an N-channel MOSFET showing the drain current ID versus drain-to-source voltage V_{DS} where curves 12, through 15 illustrate curves of increasing gate voltage V_{GS}, for example in one-volt increments. Curve 12 represents the special condition of zero-volt gate drive, i.e. V_{GS}=0, and is often referred to by the nomenclature IDSS. If a device conducts substantially no current under this bias condition, that is if IDSS is small, the device is referred to as an enhancement mode, or “normally-off” type MOSFET. Normally off devices are preferred as switches in most power electronic applications, since their default condition is “off”.

The “turn-on” or threshold voltage Vₜₒ of two different MOSFETs is illustrated in FIG. 2B in the graph of ID versus V_{GS}. MOSFET “A” shown by curve 16 has a higher threshold voltage than MOSFET “B” shown by curve 17. Provided the threshold voltage of either device remains above approximately 0.6V, the avalanche breakdown curve 18 of both devices have an off-state characteristic at V_{GS}=0 as shown in the linear-scale graph of FIG. 2C even in the single-digit microampere range. The log-scale graph of FIG. 2D, however, reveals the lower threshold device B (curve 20) has a different behavior and on a comparative basis substantially greater off-state leakage than the higher threshold device A (curve 19), despite the fact that they may exhibit the same avalanche breakdown voltage. This leakage increases with decreasing threshold and increasing temperature, especially for thresholds below 0.6V, making the device unattractive as a normally-off power switch. Beneficially, however, the linear-region on-state resistance, or “on-resistance” for the lower threshold device B is lower than that of the higher threshold device A as shown in the hyperbolic on-resistance curves 22 and 21 respectively in FIG. 2E.

FIGS. 2F and 2G illustrate a fundamental tradeoff in on-state and off-state performance of a MOSFET parametrically as a function of threshold Vₜₒ. In FIG. 2F, on-resistance RDS is shown as a function of threshold voltage Vₜₒ. Curve 23 illustrates the on-resistance of low-threshold device B is less than high-threshold device A, biased under the same gate drive condition, e.g. at V_{GS}=3V. At a lower gate bias shown by curve 24, e.g. at V_{GS}=1 V, not only is the on-resistance increased categorically, but the sensitivity of on-resistance to threshold voltage is greatly increased, where device A has a significantly higher resistance than device B.

FIG. 2G illustrates the threshold dependence of the off-state leakage I_{DSS}. Curve 25 illustrates the dependence on leakage as a function of threshold voltage, where device B exhibits higher leakages than device A. Lowering a MOSFET's threshold voltage lead to a rapid increase in leakage current. Clearly a compromise exists between the low leakage of device A and the low on-resistance of device B. To obtain sufficiently low on-resistance for operation with only one-volt of gate drive renders any silicon MOSFET too leaky to use. Raising a MOSFET's threshold by changing its construction also increases the device's on-resistance.

In addition to the tradeoff between leakage and on-resistance, a power MOSFET also exhibits a trade-off between its on-resistance and its switching losses. In devices operating at voltages less than one hundred volts and especially below thirty volts, switching losses are dominated by those losses associated with driving its gate on and off, i.e. charging and discharging its input capacitance. Such gate drive related switching losses are often referred to as “drive losses”. To this point, FIG. 3 illustrates a graph of MOSFET's gate drive voltage V_{GS} versus its on-resistance R_{DS} and on gate charge Q_{G}. Gate charge is a measure of the electrical charge necessary to charge a MOSFET's electrical input capacitance to that specific gate voltage condition. Gate charge is used in preference to predicting a transistor's behavior by capacitance since a MOSFET's capacitances are nonlinear and voltage dependent, especially over the large-signal voltage range used in switching applications. As an integral of voltage and capacitance, gate charge increases in proportion gate bias V_{GS} as illustrated by curve 27. The rapid increase in gate charge at a bias condition of (Vₜₒ+ΔV) shown by region 28 in the gate charge curve is due to charging of the MOSFET's gate to drain overlap capacitance when the device switches from off to on.

In contrast to gate charge increasing in proportion gate bias V_{GS}, curve 26 illustrates on-resistance decreases with increasing gate bias. The product of gate charge and on-resistance, or Q_{G}·R_{DS}, as shown by curve 28 in FIG. 3 exhibits a minimum value at some gate bias above the MOSFET's threshold. This minimum exemplifies the intrinsic trade-off between conduction losses (arising from on resistance) and switching losses (arising from driving the transistor's gate) in a power MOSFET. Overdriving the gate to higher voltages decreases on-resistance but increases gate charge and gate drive losses. Inadequate gate drive leads to large increases in on-resistance, especially below or near threshold voltage.

Minimizing the Q_{G}·R_{DS} product of a silicon MOSFET is difficult since changes intended to improve gate charge tend to adversely impact on-resistance. For example, doubling a transistor's size and gate width will (at best) halve its on-resistance but double its gate charge. The resulting Q_{G}·R_{DS} product is therefore unchanged, or in some cases even increased.

Designing a transistor to exhibit low on-resistance at low gate voltages, e.g. 1V, requires low threshold voltages which in turn requires the use of thinner gate oxides. Thinning the gate oxide however, not only limits the maximum safe gate voltage, but increases the gate charge. The resulting device remains un-optimized for high frequency power switching applications.

Using Other Semiconductor Materials

The compromises involving gate charge, on resistance, breakdown, and off leakage in power MOSFETs previously described represent physical phenomena fundamentally related to the semiconductor material itself, in this case silicon. If we consider these limitations as an intrinsic property of the silicon material itself, then an alternative approach to realize a low-voltage high frequency power transistor switch may employ non-silicon semiconductor materials. While silicon carbide, semiconducting diamond, and indium phosphide may hold some promise to meet this need in the future, the only material sufficiently mature for practical application today is gallium arsenide, or GaAs.

GaAs has to date however only been commercialized for use in high-frequency and small signal applications like radio frequency amplifiers and RF switches. Historically, its limited use is due to a variety of issues including high cost, low yield, and numerous device issues including fragility, and its inability to fabricate a MOSFET or any other insulated gate active device. While cost and yield issues have diminished (somewhat) over the last decade, the device issues persist.

The greatest limitation in device fabrication results from its inability to form a thermal oxide. Oxidation of gallium arsenide leads to porous leaky and poor quality dielectrics and unwanted segregation and redistribution of the crystal's binary elements and stoichiometry. Deposited oxides, nitrides, and oxy-nitrides exhibit too many surface states to be used as a MOSFET gate dielectric. Without any available dielectric, isolation between GaAs devices is also problematic, and has thwarted many commercial efforts to achieve higher levels of integration prevalent in silicon devices and silicon integrated circuits.

These issues aside, one approach successfully used to make a prior art GaAs field-effect transistor without the need for a gate oxide or high temperature processing is the metal-epitaxial-semiconductor field-effect transistor, or MESFET as shown in FIG. 4A. In cross section 30, the transistor is fabricated in a GaAs mesa 32 formed atop semi-insulating GaAs substrate 31. The device is isolated by an etched mesa to separate each device from adjacent devices prior to die separation in manufacturing. Rather than implanting and annealing dopant to form N+ regions 34, the N+ layer is grown as part of the epitaxial process used to form N-epitaxial layer 33.

The device uses a Schottky metal gate 36 formed in a shallow etched trench 35 and contact by metal electrode 38. The gate trench is etched sufficiently deep to transect N+ layer 34 into two sections, one acting as the transistor's source contacted by source metal 39, the other acting as its drain and contacted by metal 37. The Schottky metal is typically a refractory metal, typically titanium, tungsten, cobalt, or platinum chosen for the electrical properties of the junction it forms with N-GaAs layer 33. In prior art structures, the Schottky gate barrier metal 36 is located entirely inside the trench and spaced from the trench sidewall to avoid any contact with N+ layer 34. Contact between the Schottky gate and the N+ layer will result in unacceptably high gate leakage and impair the device's normal operation. The interconnect metal is chosen to make an ohmic contact with both N+ layer 34 and the Schottky gate material 36. Gold is one common interconnect material used in MESFET fabrication. Contact to the Schottky gate 36 by metal 38 occurs inside the trench, specifically where Schottky metal 36 sits atop of and extends beyond interconnect metal 38. Metal 38 does not contact epi layer 33 in the bottom of the trench.

Operation of device 30 is unipolar, where the depletion region formed by the Schottky barrier between gate material 36 and epi layer 33 is influenced by the gate potential of electrode 38, and modulates the electron flow between source 37 and drain 39. The gate 36 transects the entire mesa 32 to prevent any N+ surface leakage currents. All current must therefore flow beneath trench 35, modulated by the depletion region of the Schottky junction. Since no current is intentionally injected into the gate, the device operates as a field effect transistor, as depicted in FIG. 4B as the same schematic element 40 used for a JFET, except that the gate is Schottky and not a diffused junction. No substantial current flows through the semi-insulating substrate 31, although a buffer layer sandwich of multiple alternating material or junctions may be grown as an interface vetween substrate 31 and epi layer 33 to further reduce substrate leakage.

FIG. 4C illustrates the family of curves for a conventional MESFET which we shall here denote as a “type B” device. Curve 40 illustrates the drain current that results from operating the devices with its gate shorted to its source, i.e. V_{GS0}=0. The non-zero I_{DSS} current indicates that the device is normally on, otherwise known in MOSFET vernacular as “depletion mode”. Curve 41, 42, and 43 at increasing positive gate biases of V_{GS1}, V_{GS2}, and V_{GS3} respectively illustrates that the drain current is increased by slightly forward biasing the gate electrode. The gate can only be forward biased to the voltage at which the Schottky junction becomes forward biased and the depletion region shrinks to its minimum extent. Beyond V_{GS3}, the gate-to-source voltage becomes clamped at the Schottky's forward voltage, typically 0.7 to 0.9V. Forwarding biasing the Schottky junction at high current densities may also permanently damage the device.

FIG. 4C also illustrates that the drain current can be suppressed below I_{DSS} by further reverse biasing the Schottky junction, i.e. by applying a negative gate-to-source bias as depicted by curves 44, 45, and 46 operated at gate potentials −V_{GS4}, −V_{GS5}, −V_{GS6} respectively. The reduced current results from the increased pinching of the drain current under the gate by the reverse biased depletion region. Note that the maximum extent of the depletion region may be unable to pinch-off the drain current totally, in which case the device cannot be fully turned off. Such a device does not make a useful power switch but is still commonly used in RF (radio frequency) power and small signal amplifier applications.

### SUMMARY OF THE INVENTION

The present invention includes inventive matter regarding gate drive methods that enable the use of power MESFETs in switching regulators. The gate drive methods are preferably, but not necessarily useful in combination with the type of MESFET described in the U.S. patent application entitled “Rugged MESFET for Power Application.” This type of MESFET, referred to in this document as a “Type A” MESFET is a normally off device with low on-state resistance, low off-state drain leakage, minimal gate leakage, rugged (non-fragile) gate characteristics, robust avalanche characteristics, low turn-on voltage, low input capacitance (i.e. low gate charge), and low internal gate resistance (for fast signal propagation across the device). These characteristics make Type A MESFETs particularly suitable as power switches in Boost converters, Buck converters, Buck-boost converters, flyback converters, forward converters, full-bridge converters, and more.

Using Type A MESFETs as power switches and synchronous rectifiers in DC-to-DC switching converters requires special gate drive circuitry and techniques to prevent overdrive of the MESFET's Schottky gate inputs. Overdrive must be prevented to protect the power MESFETs from damage, avoid unwanted switching oscillations, and to avoid gate drive losses that reduce overall converter efficiency.

The present invention includes techniques for driving low and high-side (floating) MESFETS. These techniques are further characterized as static (i.e., circuits that produce stable output current and voltage and do not rely on constant switching to operate) or dynamic (i.e., circuits whose output voltage and current is determined by constant switching or AC operation). The following paragraphs describe low-side techniques and high-side techniques in turn using both static (i.e. continuous) and dynamic (i.e. always switching) circuit methods.

Static Gate Drivers with Overdrive Protection for Low-Side MESFETS

A first method for static drive of a MESFET uses a standard CMOS buffer to drive a MESFET's gate. In this type of circuit, the source of a P-channel MOSFET is connected to a battery (or other power source) and the source of an N-channel MOSFET is connected in ground. The drains of the two MOSFETs are connected to each other and their gates are connected to a common input. This configuration functions as a CMOS inverter with the inverter output being the drains of the two MOSFETs. The inverter output drives the Schottky of a MESFET and operates properly if the battery voltage is matched to the forward voltage of the Schottky.

A second method for static drive of a MESFET modifies the CMOS inverter just described by adding a second N-channel MOSFET between the battery-connected P-channel and the ground connected N-channel. The gate of the second N-channel is connected to a bias voltage VBIAS causing the second N-channel MOSFET to act as a voltage clamp limiting the inverter output to a voltage that equals to VBIAS minus the threshold voltage of second N-channel. The bias potential VBIAS is produced by any number of voltage reference techniques such as well known prior-art bandgap reference circuits or by Zener diode based reference circuits. This circuit limits MESFET gate drive over a wide range of input voltages, albeit with varying degrees of efficiency.

Another method for static MESFET drive modifies the CMOS inverter to use a low dropout (LDO) linear to regulate the voltage supplied to the source of the P-channel MOSFET. By limiting the voltage powering the CMOS inverter, the gate drive voltage supplied to the MESFET is likewise limited.

For another static MESFET drive method, a controlled current source (also known as a dependent current source) is connected to supply the gate drive for a MESFET. An N-channel MOSFET is connected between the MESFET gate and ground. The current source and MOSFET are driven out of phase, meaning that when the current source is enabled, the MOSFET is off and vice-versa. This limits the maximum current into the gate of the MESFET and thereby sets the maximum voltage of MESFET to some low value. Conversely, when the current source is disabled the N-channel MOSFET turns on discharging whatever charge is stored on the MESFET's gate to ground. This circuit limits MESFET gate drive over a wide range of input voltages, albeit with varying degrees of efficiency, so long as the current source can withstand the maximum input voltage. The adjustable current source can be implemented in a number of means such as current mirror circuits, transconductance amplifiers, current output digital to analog converters (DACs), and more.

Still another static MESFET drive method regulates the output of the CMOS inverter originally described above. This is accomplished using a resistor divider to reduce the voltage of the CMOS inverter output, reducing voltage of the gate drive to the MESFET. This circuit cannot supply MESFET gate drive over a wide range of input voltages without subjecting the gate of the MESFET to the same variation.

For another static MESFET drive method, an NPN transistor is used to supply the gate drive for a MESFET with the NPN drain connected to a battery (or other power source) and its NPN emitter connected to the MESFET gate. An N-channel MOSFET is connected between the MESFET gate and ground. The battery is also connected to the source of a P-channel MOSFET and the drain of the MOSFET is connected, via a resistor to drive the NPN transistor. This configuration of components produces a BiCMOS gate buffer where the NPN transistor acts as a voltage follower whose emitter voltage (equal to the gate voltage VG) can be driven to no higher than one base-to-emitter diode drop VBE (roughly 0.7V) less than the battery voltage V_{batt}. The maximum emitter current output from the NPN follower set by the resistance of the resistor between the P-channel drain and the NPN follower. The two MOSFETs form a CMOS inverter which in one state sources current to the gate of MESFET and in the other state connects the MESFET gate to ground. If additional voltage drop is desired, more NPN follower stages may also be cascaded, i.e. emitter to base connected per stage. This circuit cannot supply MESFET gate drive over a wide range of input voltages without subjecting the gate of the MESFET to the same variation. Alternatively, the base on the NPN follower can be powered by a voltage reference.

Yet another method for static drive of a MESFET modifies the CMOS inverter by adding a series of one or more diodes between the P-channel and N-channel MOSFETs. Each diode decreases the maximum voltage at the gate of the MESFET by one forward voltage VF is approximately 0.7V per diode. The number of diodes can be adjusted depending on the battery voltage. Shunting transistors may be added in parallel with one or more of the diodes. By enabling one or more of these transistors, the voltage drop over the series of diodes may be dynamically adjusted to match battery output, thereby limiting the range of voltages imposed on the MESFET's gate.

Dynamic Gate Drivers with Overdrive Protection for Low-Side MESFETS

A first method for dynamic drive of a MESFET uses a standard CMOS buffer to drive a capacitive voltage divider. The capacitive voltage divider, in turn drives the gate of a MESFET. In this type of circuit, the source of a P-channel MOSFET is connected to a battery (or other power source) and the source of an N-channel MOSFET is connected in ground. The drains of the two MOSFETs are connected to each other and their gates are connected to a common input. This configuration functions as a CMOS inverter with the inverter output being the drains of the two MOSFETs.

A first capacitor connects the output of the inverter to an output node. A second capacitor connects the output node to ground. A resistor is connected in parallel with the second capacitor between the output node and ground. The gate of a MESFET is driven from the voltage at the output node. The two capacitors form a dynamic voltage divider whose output voltage during constant switching is determined by the relative capacitance of the two capacitors. The parallel resistor is included to pull the gate of the MESFET to ground during its off state when switching in inhibited.

42 For a variation of the dynamic drive method just described, the pull-down resistor is replaced with a shutdown device (such as an N-channel MOSFET) that is used to dynamically ground the gate of the MESFET. The shutdown device may be activated only when the CMOS inverter is not switching or may be activated by the inverter input.

Another dynamic drive of a MESFET uses a switched capacitor network to convert a battery voltage to a lower voltage. The switched capacitor network includes two capacitors and a series of switches. The switches allow the capacitors to be dynamically switched into two different configurations as part of a repeating charge/discharge sequence. In the first of these configurations, the capacitors are connected in series between a battery of other voltage source and ground. In the second configuration, the capacitors are connected in parallel. In the second configuration, the voltage over the two parallel capacitors is one-half of the battery voltage (assuming equal capacitance). That voltage drives an LDO which, in turn drives the gate of a MESFET. An output capacitor is connected between the LDO and ground to smooth output ripple from the switched capacitor network. As battery voltage declines, the switched capacitor network can be reconfigured to supply voltage directly from the battery.

The switched capacitor network can be extended beyond the divide-by-two configuration just described. For example, by alternately connecting three capacitors in series and then in parallel, a divide-by-three network is created. The same technique may be extended to any number of capacitors.

Static and Dynamic Gate Drivers with Overdrive Protection for Floating MESFETS

A suitable method for floating dynamic drive of a MESFET uses a gate buffer to provide the gate drive for a high-side or floating MESFET. Using MESFETs in common converter topologies such as a Buck converter, a high-side MESFET is often connected in series between a battery (or other power source) and a low-side switch. The low-side switch connects, in turn to ground. For the purposes of description, it is assumed that an output node exists between the high-side MESFET and low-side switch. The gate buffer is powered by a floating capacitor. A diode is connected to allow current to flow from the battery to the floating capacitor. The capacitor is connected, in turn to the output node.

The operation of the MESFET high-side switch and the low-side switch causes the floating capacitor to operate in a two-phase sequence. In the first phase, the MESFET high-side switch is open and the low-side switch is closed. As a result, the diode and floating capacitor are connected in series between the battery and ground, charging the capacitor. In the second phase, the MESFET high-side switch is closed and the low-side switch is opened. As a result, the floating capacitor is no longer grounded. Instead, its formerly grounded side is connected to the output voltage through the high-side MESFET during its on state. This method raises the voltage available from the capacitor to its charged voltage plus the output voltage, approaching the output voltage plus the capacitor voltage after the high side MESFET completes switching. In this way, a voltage greater than battery voltage is available to power the gate buffer. In other topologies, e.g. in a synchronous boost converter, the rectifier MESFET has neither terminal tied directly to a supply rail, but rather is floating on top of the output voltage. Whether the MESFET is high side or fully floating, its gate drive must float and be able to deliver a voltage during some intervals above the battery input voltage or converter output voltage.

The gate buffer used in the circuit just described is not simply a CMOS inverter, but includes an overdrive limiting capability specifically matched to a MESFET switch. Each of the implementations described previously for static drive of low-side MESFETS may be adapted to floating gate drive. For example, the preceding description discusses a modified CMOS inverter that includes a cascode transistor biased by a voltage reference. To adapt this circuit to act as a gate buffer for a high-side MESFET, the source of the N-channel MOSFET is connected to the source of the MESFET. The ground point of the voltage reference is also connected to the source of the MESFET. A battery is connected via a diode to the source of the P-channel MOSFET is connected. Thus, the battery and diode serve as the positive supply voltage for modified CMOS inverter and the source of the MESFET serves as the ground plane. A floating capacitor is connected in parallel with the CMOS inverter between the diode and the MESFET source. As previously described, switching the MESFET causes the capacitor to be charged and then connected to the output to power the floating gate drive circuit. As a result, the voltage available to power the modified CMOS inverter exceeds the voltage available from the battery.

The same bootstrapping technique may be used to power any of the overdrive-limited static or dynamic MESFET gate drive circuits described above. In this way, the static and dynamic gate drive circuits become suitable for driving hi-side (floating) MESFETS. Alternatively, the bootstrapping floating gate drive technique may be used to only partially charge the floating bootstrap capacitor and in so doing naturally limit the high-side MESFET's gate drive.

DC-to-DC Converter Examples Using Gate-Drive-Limited MESFETs

The gate drive circuits can be used to construct MESFET-based switching regulators of all types including boost, buck and buck-boost types. This includes step-down regulators that include a single MESFET switch such as a buck regulator where the low-side rectifier function is performed by a Schottky diode or MOSFET. This also includes step up regulators that include a single MESFET switch such as a boost regulator where the floating rectifier function is performed by a Schottky diode or MOSFET. It also includes regulators that include two switching MESFETs, one performing a switching function, the other performing a rectifier function. In either case, selection of the appropriate drive circuit will ensure that switching MESFETs are driven within the correct voltage range to ensure reliable operation.

### DESCRIPTION OF FIGURES

FIG. 1 Boost switching converter using power MOSFET switch (Prior Art).

FIG. 2 Power MOSFET electrical characteristics: (A) family of drain curves (B) gate dependence of drain current for high and low Vt devices (C) avalanche breakdown characteristics (D) drain leakage (log scale) for high and low Vt devices (E) gate dependence of on-resistance for high and low Vt devices (F) threshold dependence of on-resistance (G) threshold dependence of drain leakage.

FIG. 3 V_{GS} dependence of power MOSFET gate charge and on-resistance.

FIG. 4 GaAs MESFET cross section and electrical characteristics: (A) prior-art cross section (B) symbol (C) “type B” prior-art family-of-curves (D) hypothetical “type A” family-of-curves (E) gate characteristics (F) gate dependence of on resistance for two device types.

FIG. 5 MESFET DC/DC converters: (A) boost converter (B) Buck converter.

FIG. 6 MESFET static low-side gate drivers with overdrive protection: (A) Non clamping CMOS (B) Cascode CMOS (C) LDO pre-regulated CMOS (D) LDO pre-regulator (E) controlled current source (F) current mirror (G) resistive divider (H) BiCMOS with NPN follower (I) diode ladder.

FIG. 7 MESFET dynamic low-side gate drivers with overdrive protection: (A) capacitor divider (B) capacitor divider with shutdown (C) 2-cap switched cap divider with LDO follower (D) 2-cap switched cap transfer characteristic (E) 2-cap switched cap implementation (F) 3-cap switched cap divider with LDO follower.

FIG. 8 MESFET static floating gate drivers with overdrive protection: (A) bootstrap gate drive (B) charging phase of bootstrap capacitor (C) on-phase for floating device (D) floating cascode clamp (E) floating buffer with resistor divider (F) floating drive with switched current source (G) floating LDO buffer.

FIG. 9 Floating drivers with limited bootstrap charging: (A) LDO limited charging (B) diode limited charging with DAC (C) current source controlled charging (D) switched capacitor DAC control.

FIG. 10 DC-to-DC converters combining low-side and floating over-drive protected MESFETs: (A) synchronous Buck converter (B) synchronous boost converter.

### DESCRIPTION OF INVENTION

The present invention includes inventive matter regarding specialized gate drive for a proposed power MESFET which we shall refer to in this document as a “type A” device.

Before describing the gate drive subject matter, a short description of the “type A” device is presented. A more complete description of the “type A” device and its applications is included the related applications previously identified.

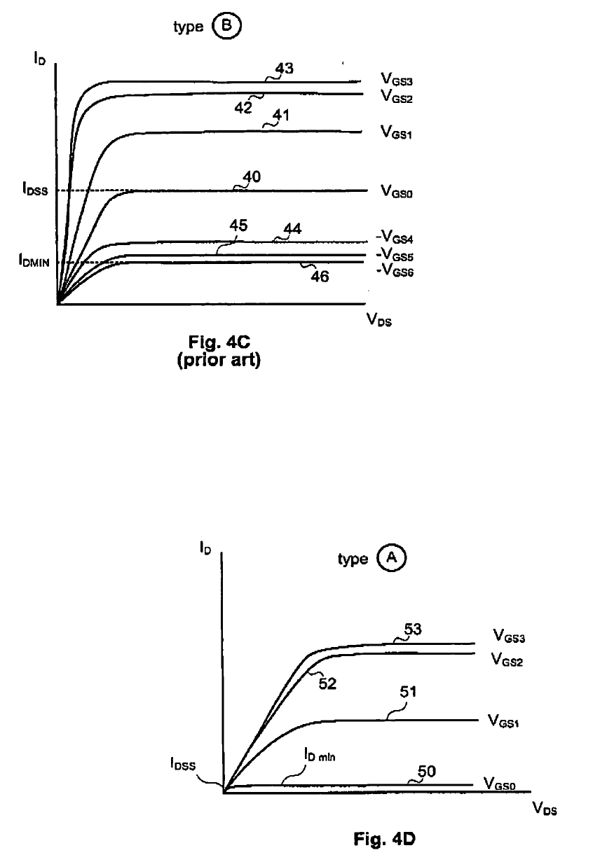

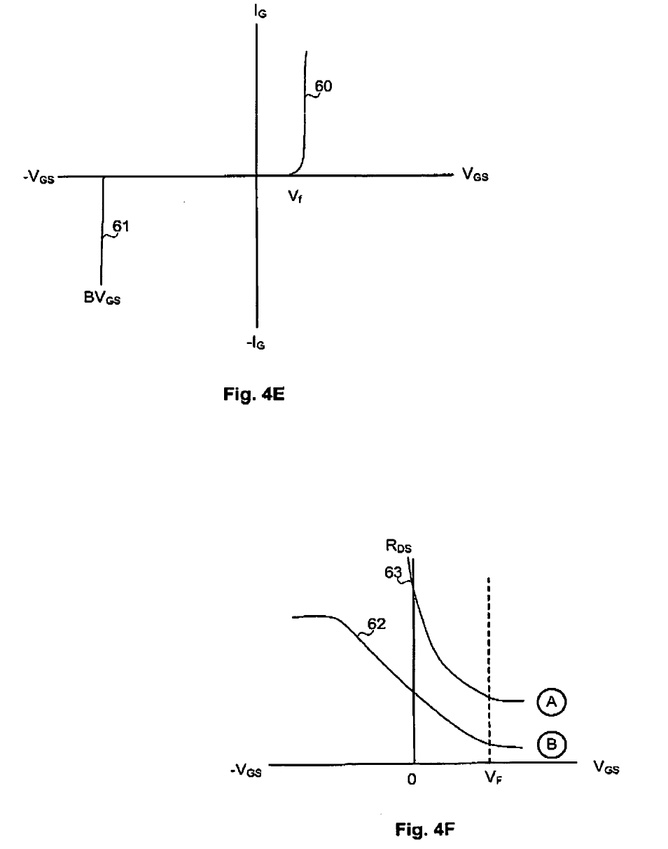

FIG. 4D illustrates how the previously described “type B” depletion-mode device would need to be adjusted to make a power switch with useful characteristics (i.e., the “type A” device). Similar to an enhancement mode MOSFET, the proposed “type A” MESFET needs to exhibit a near zero value of I_{DSS} current, i.e. the current I_{Dmin} shown as line 50 should be as low as reasonably possible at V_{GS}=0. Biasing the Schottky gate with positive potentials of V_{GS1}, V_{GS2}, and V_{GS3} results in increasing currents 51, 52, and 53, respectively, clamped to some maximum value by conduction current in the Schottky gate.

The range in gate voltages V_{GS} that a MESFET may be operated is, unlike an insulated gate device or MOSFET, bounded in two extremes as shown in FIG. 4E. In the direction of forward bias as shown by curve 60 the maximum gate bias is V_{F}, the forward bias voltage of the Schottky at the onset of conduction. In the reverse direction, line 61 represents the Schottky avalanche voltage. Extreme bias conditions, whether forward or reverse biased can damage the fragile MESFET. Moreover, driving the MESFET gate into forward conduction leads to DC power losses from gate conduction, adversely impacting the efficiency of power converters using the device.

Depending on the metal used as the gate material, the onset of gate current in the forward bias mode will vary. For common gate metals like titanium, platinum, tungsten and other refractory metals, this voltage typically ranges from 0.5V to 1V. Operating such a device with a gate bias one to two hundred millivolts below the onset of Schottky conduction results in MESFET drain conduction with minimal gate current. For example, in the case of titanium, substantial forward bias conduction current occurs above 0.65 V. Accordingly, applying a maximum gate bias of between 0.5V and 0.6V to such a device results in minimal gate current.

FIG. 4F illustrates a theoretical comparison of the linear region on-resistance of the two MESFET types as a function of V_{GS}. The vertical RDS scale as shown is logarithmic, meaning even a small change represents a large change in magnitude of resistance, even orders-of-magnitude. Under all bias conditions the proposed enhancement mode type A device exhibits a higher resistance than the prior art depletion mode type B MESFET. Forward bias, i.e. positive V_{GS} potentials decreases on-resistance of both devices as shown. At zero gate bias, the resistance of device A is essentially determined by the drain leakage current of the device while device B is still conducting substantial current, i.e. it is still “on”. Reverse biasing a MESFET's gate increases its resistance. Under such negative gate bias conditions, enhancement-mode device A exhibits a resistance which can exceed the resistance of depletion-mode type B devices by orders of magnitude. Unlike the enhancement mode device which can be turned off (except for leakage), curve 62 reveals a plateau in resistance of the depletion mode device, a condition that occurs when the gate's reverse biased depletion region reaches its maximum extent.

So while the less leaky proposed “type A” device is expected to exhibit a higher resistance than the normally on “type B” device, it still should have a usefully low value of on-resistance for power applications, typically several hundred milliohms or less in a die in an area of one square millimeter. In some applications devices having on-resistances as low as several milliohms are required. Without considering parasitic resistances (like wiring and packaging parasitics), lower device resistance is achieved by scaling the MESFET's channel width (and die area) in inverse proportion to on-resistance. Drain leakage current, unfortunately, also increases in proportion to channel width, so that excessively large devices cannot be used in applications needing extremely low channel leakages.

Ideally then, a power switch suitable for very high-frequency DC/DC conversion a normally offdevice with low on-state resistance, low off-state drain leakage, minimal gate leakage, rugged (non-fragile) gate characteristics, robust avalanche characteristics, low turn-on voltage, low input capacitance (i.e. low gate charge), and low internal gate resistance (for fast signal propagation across the device). Such a power device will then be capable of operating at high frequencies with low drive requirements, low switching losses, and low on-state conduction losses.

Implementing such a power switch using a MESFET such as the GaAs MESFET previously described, a MESFET must be substantially modified in its fabrication and its use, and may require changes in its fabrication process, mask layout, drive circuitry, packaging, and its need for protection against various potentially damaging electrical conditions.

Specifically, driving the gate of a MESFET involves special considerations. If the MESFET's gate drive is too low, e.g. below 0.5V in the previous example, the device's drain-to-source on-resistance will be undesirably high and excessive conduction losses will result. Conversely, if the gate drive is too high, e.g. over 0.65 V, gate current will flow and undesirable gate drive loss will result. In contrast MOSFETs do not exhibit a dramatic increase in gate current for slight overdrive of their gate as MESFETs do. Since nearly every battery-chemistry in use today exhibits a single-cell voltage in excess of 0.9V, with Lilon cells having voltages as high as 4.2V, special gate drive circuitry is needed to drive a MESFET and to successfully apply such a device in power switching applications.

Examples of DC/DC Converters Using Power MESFETs

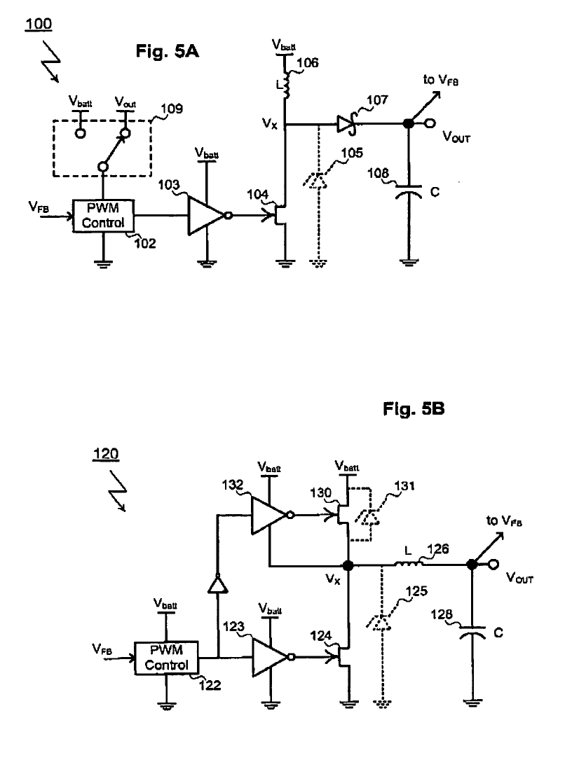

FIG. 5A illustrates an inventive boost converter for stepping-up and regulating voltages using a MESFET as the converter's power switch. In this example power MESFET 104 is switched at a high frequency by gate buffer 103 powered directly from the battery. The on-time, duty factor and switching frequency of power MESFET 1 04 is controlled by PWM circuit 102, where the PWM circuit may operate in constant frequency pulse-width-modulation (PWM) mode or may operate in a variable frequency or pulse frequency mode (PFM). PWM circuit 102 is powered by voltage selector circuit 109, which draws its power from the battery or from the output, whichever one is greater in voltage.

Voltage boosting is achieved by switching current in inductor 106. Whenever the voltage Vx rises above the output voltage, Schottky diode 107 conducts delivering power to the load and to charge output filter capacitor 108. Zener diode 105 is optionally available to provide protection against over-voltage conditions damaging the MESFET switch.

At switching frequencies of 1 MHz, inductor L is approximately can be selected to be approximately 5 μH. At 10 to 40 MHz operation however, the inductance required is 500 to 50 nH. Such small values of inductance are sufficiently small to be integrated into semiconductor packages, offering users a reduction is size, lower board assembly costs, and greater ease of use.

Gate drive buffer block 103 drives the Schottky gate input of MESFET 104. Gate buffer 103 is not just a conventional CMOS gate buffer, but must provide unique drive properties matched to MESFET 104. Failure to properly drive MESFET 104 can lead to noisy circuit operation and increased conduction losses if MESFET 104 is supplied with inadequate gate drive, i.e. where the current capability of buffer 103 is too low to charge the input capacitance of MESFET in the time required for high frequency operation, or that the output voltage of buffer 103 is too low to fully turn-on MESFET 104 into a low-resistance fully conductive operating state. Conversely, in the event that gate buffer 103 drives the gate of MESFET 104 at too high of current or too much voltage, the resulting high gate current can lead to excessive power loss, localized heating, oscillations, and even device damage. Gate buffer 103 must rapidly drive MESFET gate 104 to the proper on-state bias condition without underdriving or overdriving the device during switching transitions.

Note also that in circuit 100, gate buffer 103 and the source of MESFET 104 share a common ground connection, which in the example shown is the most negative DC potential in the circuit. Gate buffer 103 may be inverting or non-inverting.

FIG. 5B illustrates an inventive synchronous Buck converter for stepping down and regulating voltage using two power MESFETs as power switching elements—one as a switch the other as a synchronous rectifier. In this example high-side N-channel power MESFET 130 is switched at a high frequency by gate buffer 132 while low-side N-channel power MESFET 124 is switched by gate buffer 123 at the same frequency but with opposite phase as high-side device 130.

Inverter 133 provides the phase inversion between buffer 132 and 123, but ideally represents a more complex circuit used to facilitate break-before-make shoot-through protection. Shoot-through protection is needed to prevent power MESFETs 130 and 124 from both conducting simultaneously, thereby momentarily shorting out (i.e. crow-barring) the battery or power input of the converter. Both gate buffers 123 and 132 are powered directly from the battery, but buffer 132 may in some cases include “floating gate drive” circuitry to produce an output voltage driving the gate of high-side MESFET 130 to a potential greater than the battery voltage, at least temporarily or as needed.

The on-time, duty factor and switching frequency of power MESFETs 124 and 130 are controlled by PWM circuit 122, where the PWM circuit may operate in constant frequency pulse-width-modulation (PWM) mode or may operate in a variable frequency or pulse frequency mode (PFM). In step down converters, PWM circuit 122 is generally powered directly from the battery since this voltage exceeds the output voltage.

Inductor 126 is powered by the output of the power half-bridge comprising high-side MESFET 130 and low-side MESFET 124 with time voltage Vx. Voltage Vx may optionally be limited in range by Zener diodes 125 and 131, especially to protect MESFETs 130 and 124 against excessive drain voltage transients. During operation, voltage Vx is constantly switched in varying frequency or pulse width to control the average current in inductor 126 (having inductance L), which together with output capacitor 128 (having capacitance C) act as a low pass filter to remove switching noise from Vout, the converter's output.

Step-down voltage conversion is achieved by controlling the average current in inductor 126 by controlling the on time or duty factor of high-side MESFET 131, to produce an output voltage that is some fraction of the input voltage. Using fixed frequency pulse-width modulation, for example, the output voltage Vout is equal to the battery voltage multiplied by the duty factor D where D is defined as the on-time tₒₙ of high side MESFET 131 divided by the switching period T, or mathematically as D=tₒₙ/T.

Whenever high-side MESFET 130 is switched off, the voltage of Vx is driven below ground by inductor 126. During the time before low-side MESFET 124 is turned on, the inductor current recirculates by forward biasing diode 125. Once MESFET 124 turns on, current is diverted from the diode through the MESFET's channel at a reduced voltage drop, thereby improving efficiency. Low side MESFET 124 therefore acts as a synchronous rectifier.

At switching frequencies of 1 MHz, inductor L is approximately can be selected to be approximately 5 μH. At 10 to 40 MHz operation however, the inductance required is 500 to 50 nH. Such small values of inductance are sufficiently small to be integrated into semiconductor packages, offering users a reduction is size, lower board assembly costs, and greater ease of use.

In circuit 120, gate drive buffer block 123 drives the Schottky gate input of low-side MESFET 124. Gate buffer 123 is not just a conventional CMOS gate buffer, but must provide unique drive properties matched to MESFET 124. Failure to properly drive MESFET 124 can lead to loss of efficiency and increased conduction losses if MESFET 124 is supplied with inadequate gate drive, i.e. where the current capability of buffer 123 is too low to charge the input capacitance of MESFET in the time required for high frequency operation, or that the output voltage of buffer 123 is too low to fully turn-on MESFET 124 into a low-resistance fully conductive operating state. Conversely, in the event that gate buffer 123 drives the gate of MESFET 124 at too high of current or too much voltage, the resulting high gate current can lead to excessive power loss, localized heating, oscillations, and even device damage. Gate buffer 123 must rapidly drive MESFET gate 124 to the proper on-state bias condition without underdriving or overdriving the device during switching transitions.

Note also that in circuit 120, gate buffer 123 and the source of MESFET 124 share a common ground connection, which in the example shown is the most negative DC potential in the circuit. Gate buffer 123 may be inverting or non-inventing.

Also in circuit 120, gate drive buffer block 132 drives the Schottky gate input of high-side MESFET 130. Gate buffer 132 is not just a conventional CMOS gate buffer, but must provide unique drive properties matched to MESFET 130. Failure to properly drive MESFET 132 can lead to noisy operation, loss of efficiency and increased conduction losses if MESFET 132 is supplied with inadequate gate drive, i.e. where the current capability of buffer 132 is too low to charge the input capacitance of MESFET in the time required for high frequency operation, or that the output voltage of buffer 132 is too low to fully turn-on MESFET 132 into a low-resistance fully conductive operating state. Conversely, in the event that gate buffer 132 drives the gate of MESFET 132 at too high of current or too much voltage, the resulting high gate current can lead to excessive power loss, localized heating, oscillations, and even device damage. Gate buffer 132 must rapidly drive MESFET gate 130 to the proper on-state bias condition without underdriving or overdriving the device during switching transitions.

Note also that in circuit 120, gate buffer 132 and the source of MESFET 130 share a common connection to the source of MESFET 130, which in the example shown is not ground. Since the voltage Vx changes during switching the gate buffer 132 must be referenced to a moving voltage, i.e. provide a gate drive that “floats” with voltage Vx, or otherwise the risk of overdriving the gate of high-side MESFET 132 and damaging the device is too great. Gate buffer 132 may be inverting or non-inventing.

In summary, the use of GaAs MESFETs as power switches and synchronous rectifiers in DC-to-DC switching converters requires special gate drive circuitry and techniques to prevent overdrive of the Schottky gate inputs. Overdrive must be prevented to protect the power MESFETs from damage, avoid unwanted switching oscillations, and to avoid gate drive losses that reduce overall converter efficiency. In both the boost converter 100 and in synchronous Buck converter 120 examples as shown, inventive gate buffers 103 and 123 drive low-side MESFETs 104 and 124 with respect to a common source potential which is typically ground, where ground is defined as the most negative supply rail in the circuit. In a different circuit configuration, inventive gate buffer 132 in converter 120 represents a floating or high side gate drive referenced to a moving voltage, and not to ground. The same inventive gate buffers may be used to drive power MESFETs in other converter topologies not shown including Buck-boost converters, flyback converters, forward converters, full-bridge converters, and more.

Methods to Limit MESFET Gate Overdrive

Overdrive of a MESFET gate can be prevented by two methods, either by limiting the gate drive voltage by using some type of voltage divider, clamp or regulator interposed between the power source and the MESFET gate, or by limiting the maximum current flowing into the gate by some kind of current limiter or variable resistance.

The variation in the source voltage determines which circuits are applicable and preferable for limiting MESFET gate drive. If the converter is powered from a fixed or relatively fixed voltage input, most methods disclosed herein are applicable, including voltage dividers. Examples of semi-fixed voltage inputs include the output from voltage regulators.

If the input voltage of a MESFET converter varies widely, a voltage clamping or regulating action, or current-limiting technique is needed to avoid gate overdrive of the MESFET. An example of this variability is the ubiquitous lithium ion battery, or Lilon. A single cell lithium ion or lithium polymer battery typically varies from 3.0 to 4.2 volts, a 25% variation from its discharged to its fully-charged condition. Single dry cell batteries including those of NiMH (nickel metal hydride) or NiCd (nickel cadmium) electro-chemistries have similar percentage variations. The NiMH battery for example varies from 1.2V to 0.9V during discharge. Although alkaline batteries have an operating voltage range similar to NiMH, their cell voltage can increase to as high as 1.7V during charging.

Without voltage clamping or voltage regulation, the percentage variation in the power source will be manifest in the gate drive voltage. If for example, a MESFET gate drive is limited in its operational range from 0.7V (to avoid excessive gate current) to 0.5V (to avoid excessive on-resistance) the total variation is 0.2V out of a nominal condition of 0.6V, or 33% in total. Since the range of requisite gate drive is less than the percentage battery variation, the voltage divider method is an acceptable alternative to implement MESFET gate overdrive protection. If the gate drive range of the MESFET is tighter, for example to limit the maximum voltage to only 0.65V or 0.6V and still maintain a minimum drive of 0.5V, the resistor divider approach is inadequate and an absolute gate voltage control is required. The following invention descriptions describe several methods to limit MESFET gate drive. The disclosed matter includes both static and dynamic drive techniques using voltage control (or in some cases current control) to prevent overdriving the MESFET's gate.

Static Low-Side Power MESFET Gate Drive Circuits

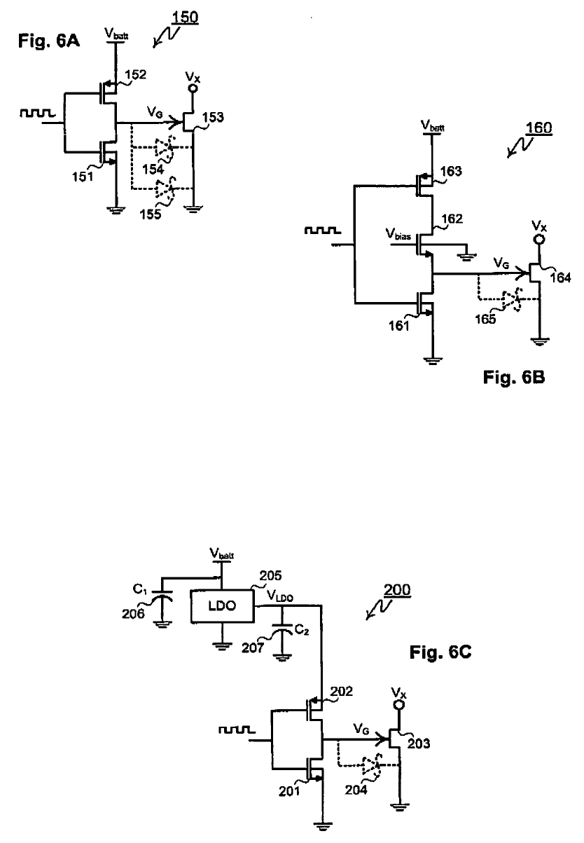

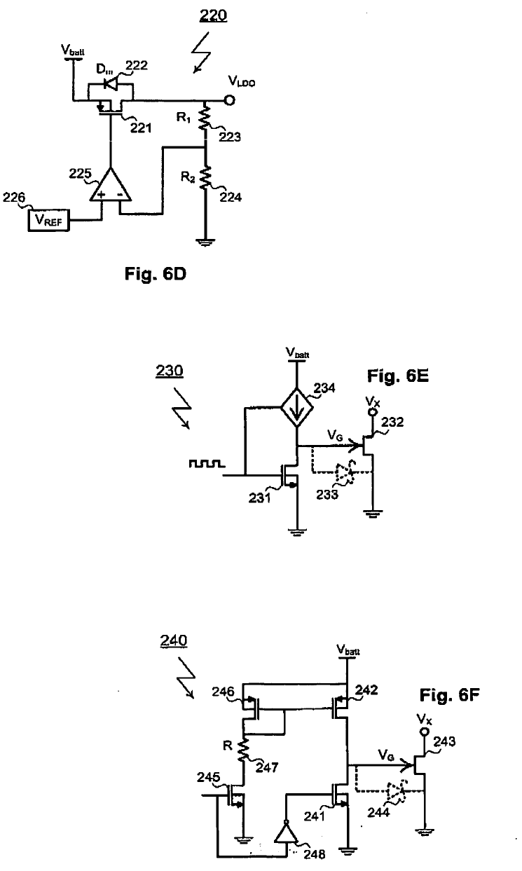

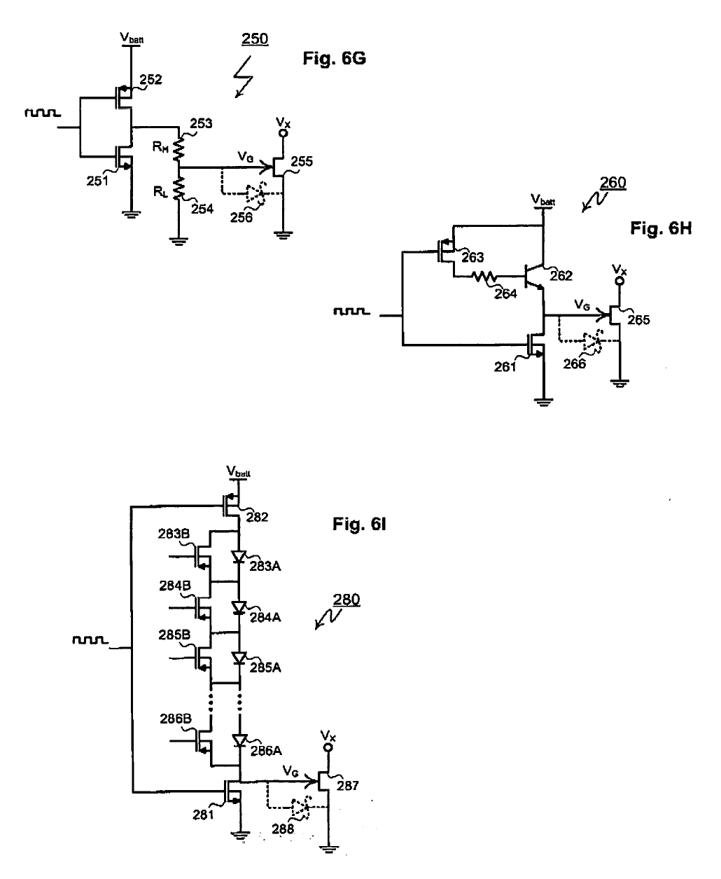

FIG. 6 illustrates a variety of means to implement low-side gate buffers (like gate buffer 103 in converter 100) using static drive circuits. A static drive circuit describes circuits whose output voltage and current is stable in a static or DC condition and does not rely on constant switching to operate.

FIG. 6A illustrates the problem of using a standard CMOS buffer to drive a MESFET's gate. In this simple circuit, gate buffer circuit 150 comprising a simple CMOS inverter drives the gate of MESFET 153. Using N-channel MOSFET 151 and P-channel MOSFET 152, the inverter drives the MESFET's gate to a voltage VG over the full range of battery voltage. In the event that battery voltage exceeds the forward voltage VF of Schottky gate diode 154, unwanted current will flow into the gate of MESFET 153 reducing efficiency and possibly damaging the device. This circuit operates properly only if the battery voltage is perfectly matched to the forward voltage of Schottky 306. Since most battery chemistries like alkaline, NiCd, or NiMH have voltages exceeding 1.2V and batteries like Lilon have cell voltages as high as 4.2V, this circuit is not generally useful, especially since GaAs MESFETs show significant gate current above 0.6V. The overdrive condition can be avoided by modifying circuitl 50 to reduce the voltage VG driving the gate or by including some means of current limiting. Alternatively, another forward biased diode 155 may divert current away from gate Schottky 154, providing the forward voltage drop of diode 155 is less than that of Schottky 154. This method does not prevent high gate drive currents and their associated power loss, but nonetheless protects MESFET 153 from gate damage resulting from excessive gate current.

Circuit 160 in FIG. 6B is a modification to the gate buffer 150 to limit the maximum gate voltage VG on MESFET 164 to below the forward voltage VF of Schottky diode 165. N-channel MOSFET 161 and P-channel MOSFET 163 act as a CMOS buffer but N-channel MOSFET 162 acts as a voltage clamp limiting the maximum gate voltage VG to a voltage that equals to VBIAS minus the threshold voltage of N-channel MOSFET 162. Since N-channel MOSFET 162 is configured as a voltage follower, any attempt by P-channel 163 to pull VG up to the battery voltage is limited because N-channel 162 will start to turn off, i.e. it can't source current above some fixed voltage chosen by design, e.g. 0.6V. The bias potential VBIAS is produced by any number of voltage reference techniques such as well known prior-art bandgap reference circuits or by Zener diode based reference circuits. This circuit limits MESFET gate drive over a wide range of input voltages, albeit with varying degrees of efficiency.

FIG. 6C illustrates another method where the voltage powering the gate buffer is limited by a low dropout (LDO) linear regulator. In the gate buffer circuit 200, LDO 205 limits the voltage powering the CMOS inverter comprising N-channel MOSFET 201 and P-channel MOSFET 202 to a voltage VF of Schottky gate diode 204 intrinsic to MESFET 203. Capacitor 206 and 207 act as input and output filters for LDO 205. This circuit limits MESFET gate drive over a wide range of input voltages, albeit with varying degrees of efficiency.

FIG. 6D illustrates one possible implementation of LDO 205. In LDO circuit 220, P-channel MOSFET 221 is operated as a current source powered by operational amplifier 225 to sustain the desired output voltage VLDO. Negative feedback from the output through resistor voltage divider comprising resistor 223 and 224 is supplied to the negative input of operational amplifier 225 which in turn drives the gate of power P-channel MOSFET 221. The feedback voltage is amplified relative to a fixed reference voltage VREF 226 to hold the output VLDO fixed despite variation in battery voltage V_{batt}. During operation, diode 222 intrinsic to P-channel MOSFET 221 remains reverse biased and does not conduct current. By regulating the voltage driving a MESFET's gate buffer, this LDO circuit 220 can supply a MESFET's gate drive over a wide range of input voltages without subjecting the gate of the MESFET to the same variation.

Another means to limit the forward bias of Schottky gate diode 233 of MESFET 232 is illustrated in the gate buffer circuit 230 of FIG. 6E; where a controlled current source (also known as a dependent current source) limits the maximum current into the gate of MESFET 232 and thereby sets the maximum voltage VG of MESFET 232 to some low VF. Whenever MESFET 232 is conducting, current source 234 is “on” and grounded MOSFET 231 remains off. Conversely when MESFET 232 is switched off the current source 234 is disabled and N-channel MOSFET 231 is turned on, thereby grounding the gate of MESFET 232 and discharging whatever charge is stored on the MESFET's gate. This circuit limits MESFET gate drive over a wide range of input voltages, albeit with varying degrees of efficiency, so long that the current source can withstand the maximum input voltage. The adjustable current source can be implemented in a number of means such as current mirror circuits, transconductance amplifiers, current output digital to analog converters (DACs), and more.

FIG. 6F illustrates one possible implementation gate buffer circuit 240 using a current source. In circuit 240, N-channel MOSFET 245, P-channel MOSFETs 246 and 242, and resistor 247 forms a current mirror, emulating the function of current source 234. The output of the current mirror on the drain of P-channel MOSFET 242 powers the gate of MESFET 243. The value R of resistor 247 is selected to limit the maximum current conducted by gate Schottky diode 244. N-channel MOSFET 241 is driven by inverter 248 out of phrase with N-channel MOSFET 245 and the current source to shut off the MESFET (i.e. ground its gate) whenever the current source is disabled.

In FIG. 6G, gate buffer circuit 250 drives the gate of power MESFET 255 to a voltage VG using resistor voltage divider 253 and 254 along with N-channel MOSFET 251 and P-channel MOSFET 252. In the event that battery voltage exceeds the forward diode voltage VF of gate Schottky diode 256, unwanted current will flow into the gate of MESFET 255 reducing efficiency and possibly damaging the device. To lower the maximum output voltage, circuit 250 choose resistor 253 and 254 as the input of the buffer 256 to lower the resist divided ratio. This circuit cannot supply MESFET gate drive over a wide range of input voltages without subjecting the gate of the MESFET to the same variation.

In FIG. 6H, circuit 260 comprises a BiCMOS gate buffer where NPN 262 acts as a voltage follower whose emitter voltage VG can be driven to no higher than one base-to-emitter diode drop VBE (roughly 0.7V) less than the battery voltage V_{batt}. The maximum emitter current output from NPN follower 262 is set by the resistance R of resistor 264. P-channel 263 and N-channel 261 form a CMOS inverter which in one state enables gate driver 262 to source current to the gate of MESFET 265 and in the other state disables NPN 262 and enables N-channel pull down device 261, thereby shutting off MESFET 265. If additional voltage drop is desired, more NPN follower stages may also be cascaded, i.e. emitter to base connected per stage. This circuit cannot supply MESFET gate drive over a wide range of input voltages without subjecting the gate of the MESFET to the same variation. Alternatively, the base on NPN follower 262 can be powered by a voltage reference.

In FIG. 61, numerous forward-biased diodes 283A, 284A, 285A, and 286A are employed to decrease the output voltage of gate buffer circuit 280 driving the gate of MESFET 287 and to limit the forward biasing of intrinsic Schottky 288. P-channel 282 and N-channel 281 form a CMOS inverter driving the gate of MESFET 287, where the maximum output voltage of the on-state is (V_{batt}−n·VF) where n is the number of PN diodes connected in series (e.g. four diodes are shown), and where VF is approximately 0.7V per diode. The number of diodes can be adjusted depending on the battery voltage.

Once preset in circuit design, the voltage translation function is fixed unless transistors are used to shunt some number of diodes in real time. Therefore, without controlled shunting transistors, this circuit cannot supply MESFET gate drive over a wide range of input voltages without subjecting the gate of the MESFET to the same variation. By adding transistors 283B, 284B, 285B and 286D, the voltage level translation can be adjusted digitally, by turning the gates on and off as need be. Such functionality is similar to digital to analog converters except that it is matched to the MESFET's gate drive requirement.

Dynamic Low-Side Power MESFET Gate Drive Circuits

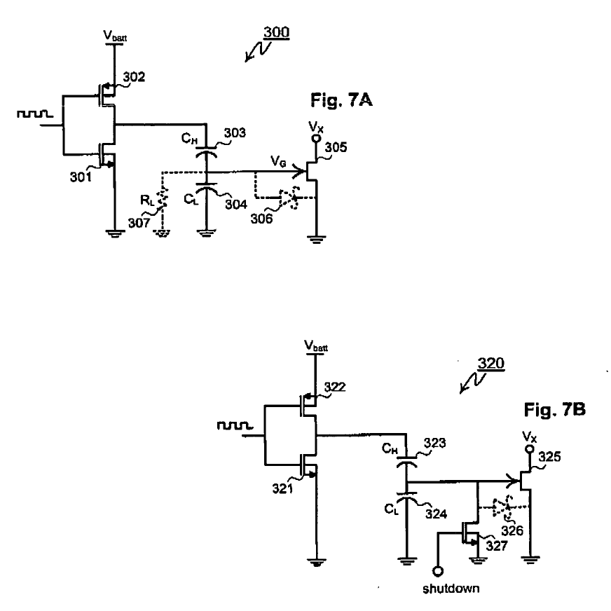

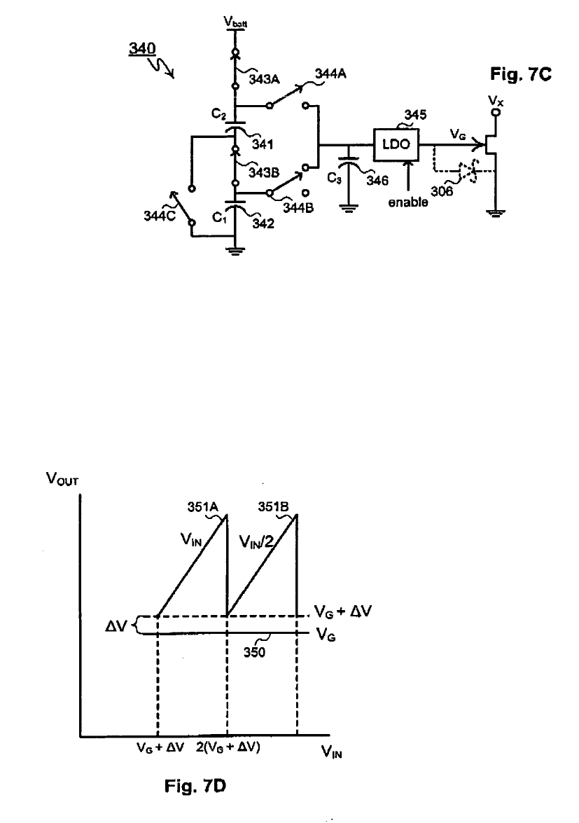

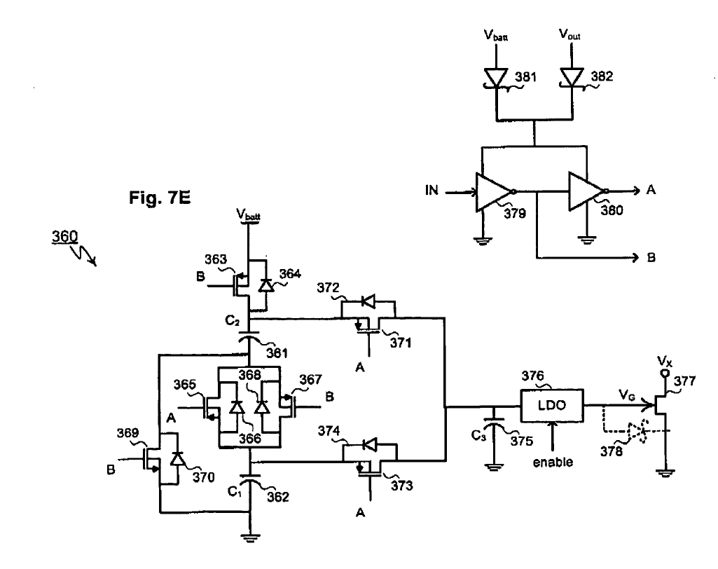

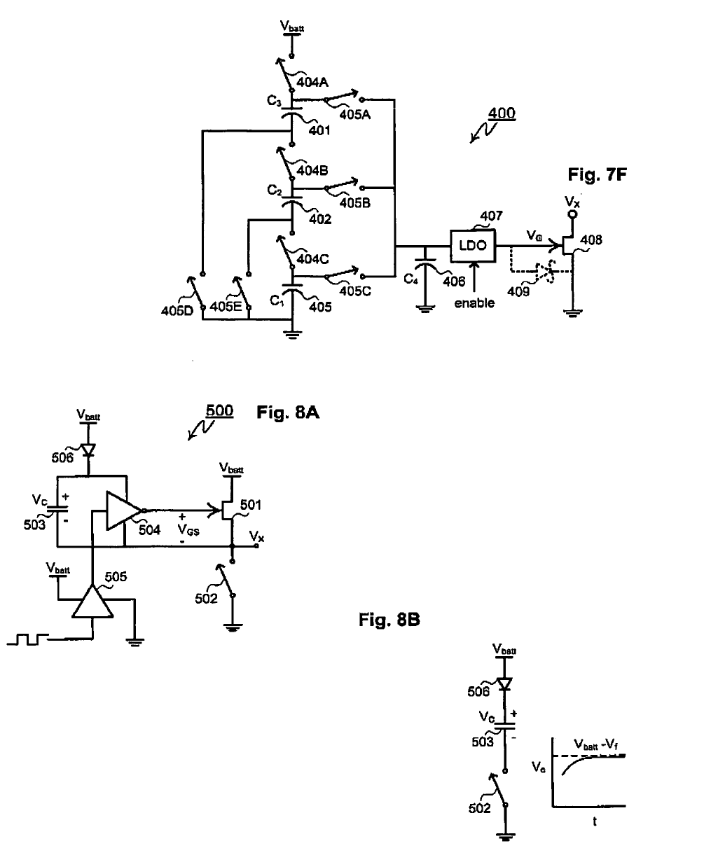

FIG. 7 illustrates a variety of means to implement low-side gate buffers (like gate buffer 103 in converter 100) using dynamic drive circuits. A dynamic drive circuit describes circuits whose output voltage and current is determined by constant switching or AC operation and in the absence of switching defaults into an off state or floating condition. Floating conditions are, however, not compatible with power applications as transient conditions can give to unwanted and spurious turn on of “off-state” power devices.

Circuit 300 in FIG. 7A comprises a dynamic circuit to limit the maximum gate voltage VG on MESFET 305 to below the forward voltage VF of Schottky diode 306 using a capacitive voltage divider. In this circuit N-channel MOSFET 301 and P-channel MOSFET 302 act as a CMOS buffer operated under the condition of continuous switching. Capacitors 303 and 304 having capacitances CH and CL respectively, form a dynamic voltage divider whose output voltage during constant switching is equal to [(V_{batt}·CL)/(CH+CL)]. Resistor 307 having resistor RL is included to pull the gate of MESFET 305 to ground during its off state when switching in inhibited to avoid the aforementioned floating gate concerns. In circuit 300, the switching frequency of the clock used to AC couple the gate drive to the MESFET switches at the same frequency as MESFET 305, but it may be operated at a higher frequency if so desired. Furthermore the conversion ratio of the capacitor network is fixed, and as a consequence, variations in the battery voltage will cause the MESFET gate voltage to change in proportion. Such change is undesirable and unless clamped by a diode to some maximum voltage, may overdrive the gate during the condition of a fully charged battery.

Circuit 320 in FIG. 7B illustrates a variant of circuit 300 with a CMOS inverter comprising N-channel 321 and P-channel 322, a capacitive voltage divider comprising capacitors 323 and 324, power MESFET 325 with intrinsic Schottky 326, and shutdown N-channel device 327. Capacitors 323 and 324 having capacitances CH and CL respectively, form a dynamic voltage divider whose output voltage during constant switching is equal to [(V_{batt}·CL)/(CH+CL]. In an off state, shutdown device 327 is used to hold MESFET 325 into an off condition whenever the CMOS buffer is not switching. Alternatively, the gate of N-channel 327 can be tied to the input of the inverter constituting transistors 322 and 321, where the off condition requires a logical “high” input state. In circuit 320, the switching frequency of the clock used to AC couple the gate drive to the MESFET switches at the same frequency as MESFET 320 although a higher frequency may also be employed. Furthermore the conversion ratio of the capacitor network is fixed, and as a consequence, variations in the battery voltage will cause the MESFET gate voltage to change. Such change is undesirable and unless clamped to some maximum voltage may overdrive the gate, especially during the condition of a fully charged battery.

In FIG. 7C, a switched capacitor network is employed to convert the battery voltage to a lower voltage. In circuit 340, a matrix comprising five switches (constructed using transistors) and two capacitors performs the primary voltage conversion function, where low-dropout regulator 345 is used to provide voltage regulation for the MESFET's gate drive. Operation of the switched capacitor circuit (also referred to as a charge pump circuit) occurs dynamically and cyclically in two alternating steps. In the first cycle, switches 343A and 343B are closed allowing capacitors 341 and 342 to charge in series. If capacitors 341 and 342 have equal capacitance C, i.e. C₁=C₂≡C, during charging the voltage will be divided in two, with half the voltage present of each capacitor. During the charging cycle switches 344A, 344B, and 344C remain off while the capacitors charge. In the next cycle, switches 344A and 344B open, disconnecting the capacitors from the battery input and from one another. During this time, switches 344A and 344B are closed, connecting the positively charged terminal of capacitors 341 and 342 to capacitor 346. Switch 344C is also closed connecting the negative side of capacitor 341 to ground, thereby essentially paralleling capacitors 341, 342 and 346, and allowing excess charge to drain from the newly charged capacitors into reservoir capacitor 346. This circuit limits MESFET gate drive over a wide range of input voltages, albeit with varying degrees of efficiency.

The cycle then repeats at some high frequency, preferable 1 MHz or higher. In the event that the input voltage drops too low to produce the desired output voltage using the divide-by-two characteristic, capacitor switching operation can be suspended, and both switches 343A and 344A can be turned on, connecting the battery directly to reservoir capacitor 346, which also acts as the input filter capacitor to low-dropout (LDO) linear regulator 345. This feature is illustrated in the graph of output versus input voltage shown in FIG. 7D. To produce a desired output voltage VG shown by line 350, the minimum output of the switched capacitor network must be some ΔV voltage above VG, with a minimum output of (ΔV+VG). For charged batteries, i.e. whenever the battery input exceeds 2·(ΔV +VG), the charge pump operates in divide by two mode. Below that battery voltage, the converter switches to 1X mode, meaning a direct battery connection. Since less voltage is present across the LDO, the efficiency of the gate drive circuit is improved.

Circuit 360 in FIG. 7E illustrates one possible implementation of circuit 340, where the switches have been replaced by transistors—specifically where switches 343A, 344A and 344B have been replaced by P-channels 363, 371 and 373 respectively (and connected where intrinsic diodes 364, 372 and 374 remain reverse biased); where switch 344C has been replaced by N-channel 369 (with intrinsic diode 370 reverse biased); and where switch 343B has been replaced by a complementary switch comprising N-channel 365 and P-channel 367 (having reverse biased intrinsic diodes 366 and 368). Gate control for phase A and phase B devices is provided by inverting buffers 379 and 380, powered by the battery or optionally by the output of the DC-to-DC converter itself, the highest voltage selected by diodes 381 and 382 or any equivalent function transistor circuit.

The output of LDO 376 drives the gate of MESFET 377 so not as to overdrive intrinsic Schottky diode 378. Since capacitor 346 filters the switching transitions of the charge pump circuit, the output of the switched capacitor network is essentially DC with some AC ripple. The toggling of MESFET 347 needed for operation in a switching power supply circuit is performed by the enable function of LDO 376, acting as a gate buffer with an output at zero or at some predetermined regulated voltage. This circuit limits MESFET gate drive over a wide range of input voltages, albeit with varying degrees of efficiency.

The limitation of circuits 340 and 360 is they are only capable of lossless divide-by-two conversion. For a one cell NiMH battery with 1.2V input and a 0.5V gate drive this circuit works efficiently. But for lithium ion batteries with a 3.0 to 4.2V range, a divide-by-two charge pump is inadequate to improve gate drive efficiency for a 0.5V or 0.6V MESFET input. In such case, the charge pump circuit can be modified to have three, four or more stages, as need be. For example using a divide-by-four charge pump, a lithium ion battery would produce an output voltage of 0.75V to 1.05V over the normal Lilon battery operating range, capable of driving a MESFET with a 0.6V gate with 60% to over 75% drive efficiency. Without the charge pump circuit, drive efficiency is reduced to around to 0.5V/3.6V or only 16%.

As an example FIG. 7F illustrates divide-by-three charge pump circuit 400 having three capacitors 401, 402, and 403, three charging switches 404A, 404B, 404C, three discharging switches 405A, 405B, and 405C, and two ground switches 405D and 405E along with reservoir capacitor 406, LDO 407, and grounded MESFET 408 with intrinsic Schottky gate 409. Operation involves the alternating charging of the three capacitors in series (through the 404 switches), and the discharging of the paralleled capacitors (through the 405 switches). For each new capacitor, three added switches must be included, namely a charging switch (like 404A), a discharging switch (like 405A) and a ground switch (like 405D). Circuit cost and area must be traded against efficiency. This circuit constrains MESFET gate drive over a wide range of input voltages, albeit with varying degrees of efficiency.

Dynamic Power MESFET Floating Gate Drive Circuits

The use of an N-channel MESFET as a high-side or floating switch requires the use of a gate drive not circuit not referenced to ground. Such floating gate drive circuits must maintain a controlled gate-to-source bias despite having a source voltage that changes during operation.

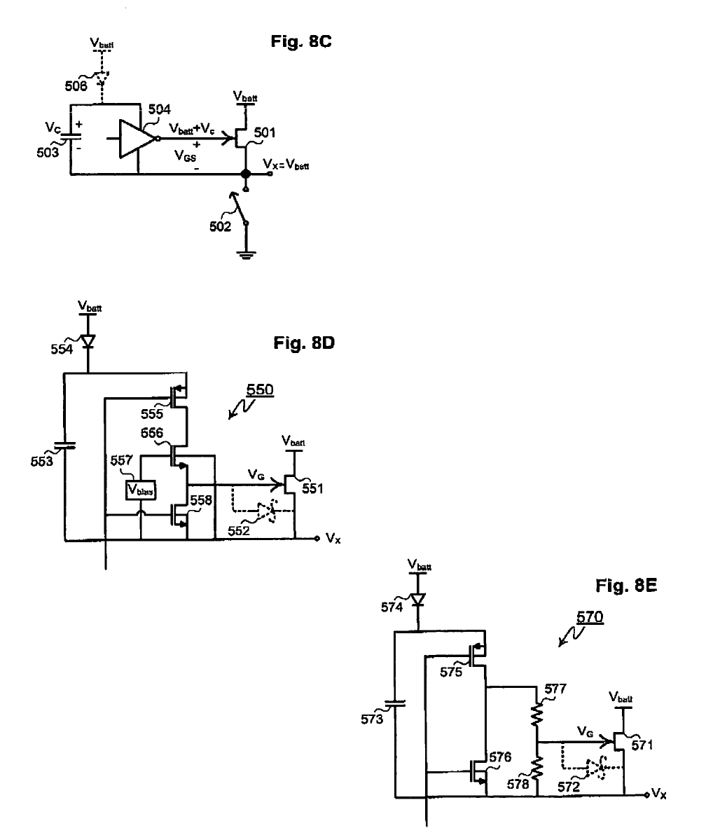

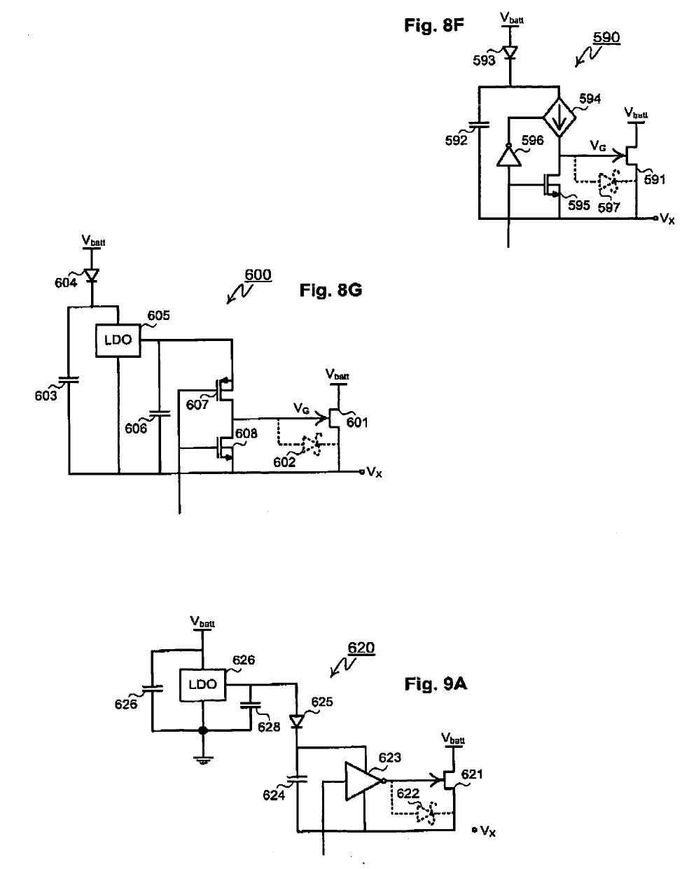

FIG. 8A illustrates one implementation of a high-side MESFET driver using an overdrive limited “bootstrap” circuit. In circuit 500, MESFET 501 is driven by an over-drive protected gate buffer 504 referenced to the source potential of MESFET 501, specifically voltage Vx. Gate buffer 504 is powered by floating capacitor 503, charged through diode 506 whenever Vx is biased near ground, i.e. whenever MESFET 501 is turned off and switch 502 is closed. Switch 502 represents any low-side switch comprising a MESFET or MOSFET. The logic input for gate buffer 504 is driven by inverter 505. Gate buffer 504 is not simply a CMOS inverter, but with overdrive limiting capability specifically matched to a MESFET switch. The aforementioned circuit techniques (shown in FIG. 6 and 7) can be adapted to floating drives circuits

Bootstrap circuit operation comprises two-phase switching synchronous to the power device switching. In charging phase shown in FIG. 8B, capacitor 503 is charged through bootstrap diode 506 whenever switch 502 is closed. Capacitor 503 charges to a voltage V_{c} approaching a voltage (V_{batt}−VF).

In the driver phase shown in FIG. 8C, switch 502 is opened while buffer 504 is turned-on to drive MESFET 501, with power supplied to the buffer by the stored charge on capacitor 503. Since MESFET 501 is biased into its “on” state, its resistance is low and the voltage Vx is essentially driven to V_{batt}. Since the voltage on a capacitor cannot change instantly, the voltage on the positive terminal of capacitor 503 jumps to (Vx+V_{c})≈(V_{batt}+V_{c}), a voltage above the battery voltage. The voltage on the positive terminal of capacitor 503 also reverse biases bootstrap diode 506.

Implementation of high-side MESFET driver circuitry 500 may adapt the same overdrive protection circuit methods illustrated in FIG. 6 and FIG. 7 except that the floating drive circuitry must be referenced to the source of the high side MESFET rather than to ground.

For example, adapting low-side MESFET driver circuit 160 for high-side drive is illustrated in circuit 550 of FIG. 8D. In this implementation the drain of high-side N-channel MESFET 551 is connected to V_{batt} and its source acts as its output, i.e. the device acts as a source-follower configured transistor. In this circuit, the gate-to-source drive is voltage is limited by cascode transistor 556 biased by voltage reference 557 to prevent overdriving intrinsic Schottky 552. On-off switching is performed by CMOS buffer comprising P-channel 555 and N-channel 558, powered by bootstrap capacitor 553 and bootstrap diode 554. The source of N-channel 558, MESFET 551, bias circuit 557, and capacitor 553 all share a common connection, which is also the output of the source follower power device.

In this circuit, capacitor 553 is charged to (V_{batt}−VF) without limiting the charging voltage. Drive to MESFET 551 is instead limited by the cascode action of N-channel MOSFET 556, not by limiting the voltage on bootstrap capacitor 553. This circuit limits MESFET gate drive over a wide range of input voltages, albeit with varying degrees of efficiency.

In circuit 570 circuit of FIG. 8E a resistor divider comprising resistor 577 and 578 drives the gate of MESFET 571 with its intrinsic gate Schottky 572, powered by capacitor 573, bootstrap diode 574, and CMOS buffer constituting P-channel 575 and N-channel 576. As a floating driver, capacitor 573, N-channel 576, resistor 578, all share a common connection with the output of the MESFET 571 source follower. In this circuit, capacitor 573 is charged to (V_{batt}−VF) without limiting the capacitor's charging voltage. Drive to MESFET 571 is limited by the resistor divider and not by limiting the voltage on bootstrap capacitor 573. This circuit, similar to 570 in FIG. 8E, cannot supply MESFET gate drive over a wide range of input voltages without subjecting the gate of the MESFET to the same variation.

Circuit 590 of FIG. 8F illustrates a floating drive using variable current source 594 driving MESFET follower 591 with intrinsic Schottky 597. Using an adjustable or programmable current source, the maximum voltage and overdrive of the gate of MESFET 591 is limited by the maximum current allowed for Schottky gate conduction. The current source is turned on and off by logic signal from inverter 596, driven out of phase with pull-down N-channel transistor 595. Current source 594 is powered by floating capacitor 592 and bootstrap diode 593 and can therefore source currents to gate potentials above V_{batt}. As a floating driver, capacitor 592, N-channel 595, all share a common connection with the output of the MESFET 591 source follower. In this circuit, capacitor 592 is charged to (V_{batt}−VF) without limiting the charging voltage. Drive to MESFET 591 is limited by the resistor divider, not by limiting the voltage on bootstrap capacitor 592. This circuit, similar to circuit 230 in FIG. 6E, cannot supply MESFET gate drive over a wide range of input voltages without subjecting the gate of the MESFET to the same variation.

Circuit 600 shown in FIG. 8G uses LDO 605 to power the gate of MESFET 601 and limit the overdrive of intrinsic gate Schottky diode 602. Switching is controlled through the CMOS inverter comprising P-channel 607 and N-channel 608. The entire circuit is powered by bootstrap capacitor 603 powered through bootstrap diode 604. As a floating driver, capacitor 603, N-channel 608, and LDO 605, all share a common connection with the output of the source follower device MESFET 601. In this circuit, capacitor 603 is charged to (V_{batt}−VF) without limiting the charging voltage. Drive to MESFET 601 is limited by the LDO, not by limiting the charging voltage on bootstrap capacitor 603. This circuit, similar to circuit 600 in FIG. 6C limits MESFET gate drive over a wide range of input voltages, albeit with varying degrees of efficiency.

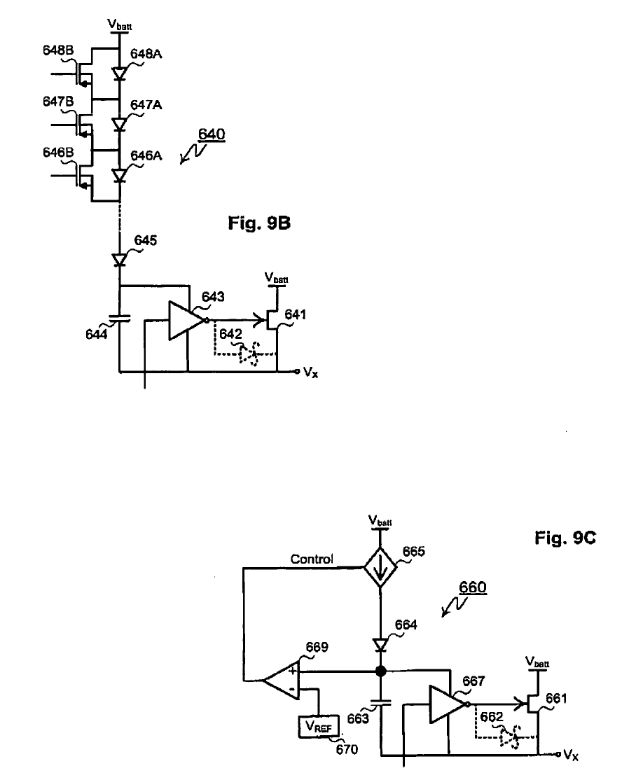

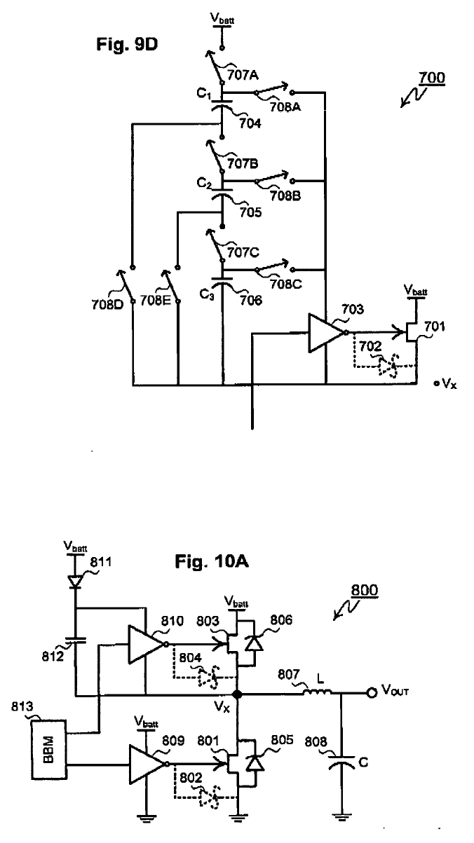

The high-side MESFET gate-drive circuits of FIG. 8 utilize a fully charged floating bootstrap capacitor powering a gate drive circuit that's limits overdrive by limiting voltage or current. Rather than limiting the maximum gate drive of the MESFET during discharge or the floating bootstrap capacitor, another method to prevent overdrive of the gate of a floating or high-side MESFET is to limit the charging of the floating capacitor as illustrated by FIG. 9.

For example in circuit 620 shown in FIG. 9A, LDO 626 which is powered directly from the battery to a voltage V_{batt}, limits the voltage to which bootstrap capacitor 624 is charged. Input and output capacitors 627 and 628 stabilize LDO 626 from oscillation. The output voltage VLDO of LDO 626 supplies bootstrap capacitor 624 through bootstrap diode 625 which in turn powers gate buffer 623. Gate buffer 623 may be a simple CMOS inverter or an overdrive-limited buffer to drive the gate of MESFET 621 and its intrinsic gate Schottky 622. As a floating driver, capacitor 624 and buffer 623 share a common connection with the output of the source follower comprising MESFET 621. In this circuit, capacitor 624 is charged not to (V_{batt}−VF) but to the lower voltage (VLDO−VF) by limiting the charging voltage. Drive to MESFET 601 is therefore not limited to gate buffer 623. This circuit limits MESFET gate drive over a wide range of input voltages depending on the voltage rating of LDO 626, albeit with varying degrees of efficiency.

In circuit 640 shown in FIG. 9B, the charging of bootstrap capacitor 644 is limited in voltage by charging bootstrap capacitor 644 through a series of diodes 645, 646A, 647A and 648A. The number of diodes can be adjusted to charge the bootstrap capacitor to a predefined voltage, either by hardwired circuitry or dynamically adjusted. In this circuit, capacitor 624 is charged to a voltage (V_{batt}−n·VF) where n is the number of forward biased diodes charging the capacitor. One method to dynamically adjust the charging voltage of capacitor 644 is by shorting out the charging diodes 646A, 647A and 648A with P-channel MOSFETs 646B, 647B and 648B, respectively, where the diodes may be intrinsic to the P-channel transistors or may be separate diodes. This action is similar to a digital-to-analog converter circuit, or DAC, technique. Gate buffer 643 which drives the gate of MESFET 641 and its intrinsic Schottky gate diode 642 may be a simple CMOS inverter or may be an overdrive protected circuit. Like the previous circuit in circuit 660, capacitor 644 is charged not to (V_{batt}−VF) but to the lower voltage (V_{batt}−n·VF) by limiting the charging voltage. This circuit constrains MESFET gate drive over a wide range of input voltages, albeit with varying degrees of efficiency.

In circuit 660 shown in FIG. 9C, bootstrap capacitor 663 is charged to a controlled voltage by controlled current source 665 through bootstrap diode 664. The charging voltage ΔV of capacitor 663 is therefore not (V_{batt}−VF) but instead is ΔV=(I·Δt/C) where I is the charging current of diode 665, Δt is the charging time, and C is the capacitance of capacitor 663. Charging may be controlled in a linear feedback circuit where gain stage 669, voltage reference 670 and current source 665 form a transconductance amplifier. Alternatively, element 669 may be operated as a comparator, thereby digitally switching a fixed current source 665 into an on state whenever the capacitor voltage is less than Vref, and shutting it off whenever the capacitor voltage exceeds VREF. Capacitor 663 then supplies power to gate buffer 667, which in turn drives MESFET 661 and intrinsic gate diode 662 without overdriving the gate. This circuit, similar to a current-output DAC but designed specifically for MESFET dive, limits MESFET gate drive over a wide range of input voltages, albeit with varying degrees of efficiency.

FIG. 9D illustrates circuit 700 using a switched capacitor network in place of a bootstrap capacitor. Capacitors 704, 705, and 706 are alternatively charged through switches 707A, 707B, and 707C and then discharged through switches 708A, 708B, 708C, 708D and 708E. During charging, the capacitors are series connected and behave as a voltage divider, dividing the voltage evenly in the event that the capacitances are of equal magnitude, namely C=C₁=C₂=C₃. In the discharge cycle, the capacitances are in parallel and supply power to gate buffer 703 which in turn drives the gate of MESFET 701 with intrinsic Schottky gate diode 702. This circuit limits MESFET gate drive over a wide range of input voltages, albeit with varying degrees of efficiency. Switched capacitor methods may be combined with other gate drive limiting circuits to protect a MESFET's gate.

DC-to-DC Converter Examples Using Gate-Drive-Limited MESFETs

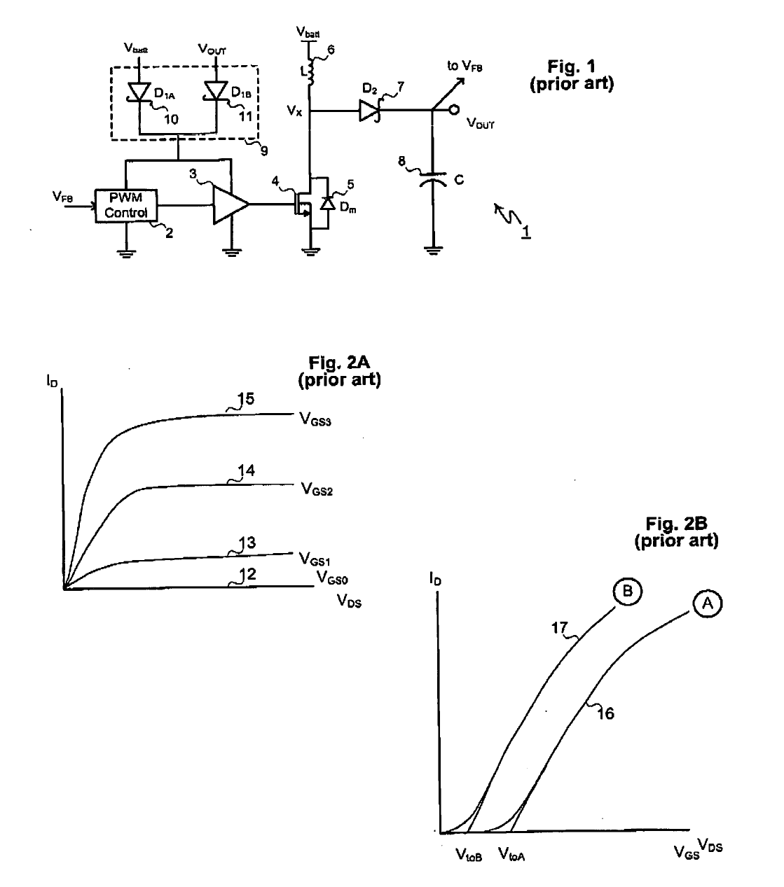

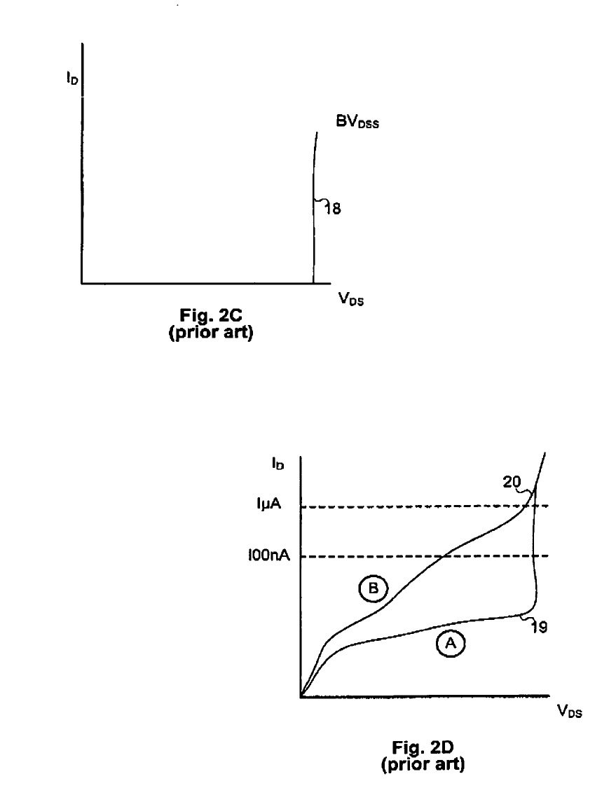

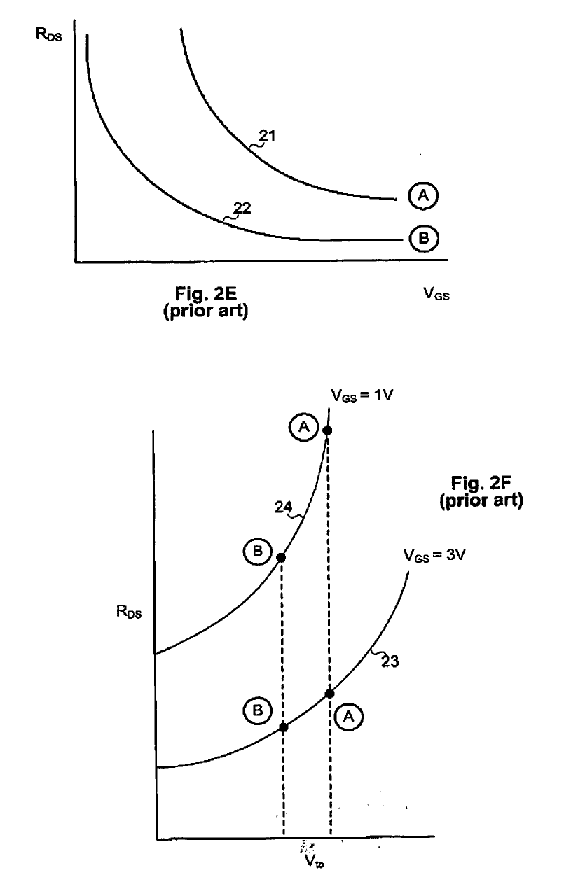

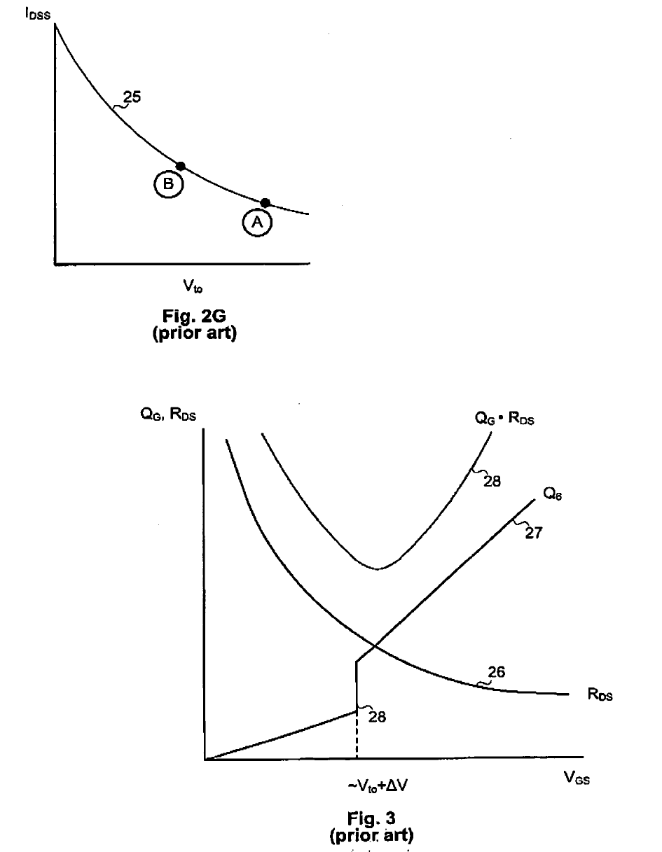

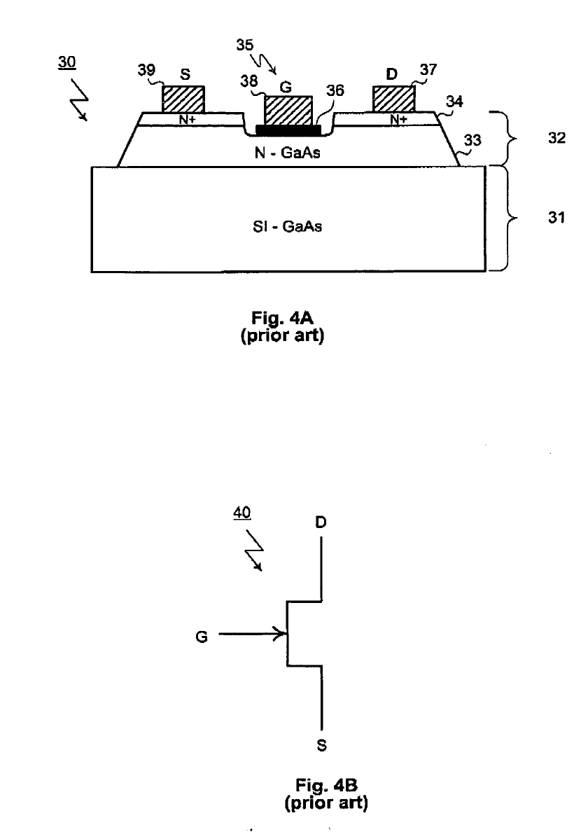

FIG. 1 0 illustrates some representative examples of common DC-to-DC converter topologies employing the aforementioned grounded and floating MESFET gate drive circuit techniques.

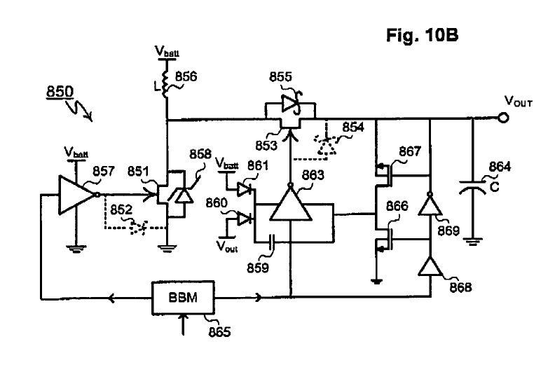

In the MESFET Buck converter 800 of FIG. 10A, low-side MESFET 801 (with intrinsic gate Schottky diode 802) is driven by inventive drive-limited grounded gate buffer 809, while high-side source follower MESFET 803 (with intrinsic gate Schottky diode 804) is powered by inventive floating drive-limited gate buffer 810 and floating capacitor 812, charged through bootstrap diode 811. Floating gate drive circuit 810 is referenced to the source of high-side MESFET 803, which is also the Vx node connected to inductor 807, and is not referenced to ground. Timing of low-side and high-side MESFET conduction is controlled by break-before-make (BBM) circuit 813. MESFETs 801 and 803 form a totem-pole power half-bridge, which when switched at a high frequency, controls the average current in inductor 807, and using feedback and pulse-width or variable-frequency control, can control the output voltage present on filter capacitor 808. Zener diodes 805 and 806 are included to protect MESFETs 801 and 803 from experiencing excessive drain-to-source voltages or noise spikes.

In the MESFET boost converter 850 of FIG. 10B, low-side MESFET 851 (with intrinsic gate Schottky diode 852) is driven by inventive drive-limited grounded gate buffer 857, while floating synchronous rectifier MESFET 853 (with intrinsic gate Schottky diode 854) is powered by inventive floating drive-limited gate buffer 863 and floating capacitor 859, charged through bootstrap diodes 860 or 861. Floating gate drive circuit 863 is not reference to a fixed potential such as the source of floating synchronous rectifier MESFET 853, which is the output of the converter, but instead is switched between the output potential and ground with MOSFETs 866 and 867 driven by gate buffers 868 and 869. Timing of low-side and synchronous rectifier MESFET conduction is controlled by break-before-make (BBM) circuit 866. Whenever rectifier MESFET is on, gate buffer 863 and bootstrap capacitor 859 are biased to the output by turning on MOSFET 867 while MOSFET 866 remains off. During the time when low side MESFET switch 851 is conducting, gate buffer 863 and capacitor 859 are disconnected from the output, and instead biased to ground through MOSFET 866 to facilitate charging of bootstrap capacitor 859. MESFETs 801 and 803 form a power half-bridge, which when switched at a high frequency, controls the average current in inductor 857, and using feedback and pulse-width or variable-frequency control, can control the output voltage present on filter capacitor 864. Zener diode 858 is included to protect MESFET 851 and indirectly to protect MESFET 853 from experiencing excessive drain-to-source voltages or noise spikes. Schottky diode 855 is included to carry converter inductor current whenever both MESFET 851 and 853 are turned off, i.e. during the break-before-make interval needed to prevent shoot-through conduction.

The examples shown may employ any combination of grounded and floating static or dynamic inventive gate buffer circuits described so long as the buffer circuit limits the gate voltage or current of the MESFET switches. The same techniques may be applied to other converter topologies, not shown here, but should be obvious to anyone skilled in the art of DC-to-DC switching converters and voltage regulators. Additionally, while P-channel MESFETs are not readily available in GaAs, the disclosed gate drive circuits can be adapted for driving such devices using the same principles to prevent gate overdrive.

What is claimed is:

1. A gate drive circuit configured to drive the gate of a N-channel MESFET where the gate drive circuit limits the maximum forward biasing of the Schottky gate intrinsic to the MESFET to a voltage where no substantial DC conduction current flows.

2. A circuit as recited in claim 1 where the MESFET is a normally off type.

3. A circuit as recited in claim 1 where the MESFET comprises GaAs.

4. A circuit as recited in claim 1 where the gate-to-source voltage of the MESFET is limited to a maximum forward bias of 0.7V.

5. A circuit as recited in claim 1 where the gate-to-source voltage of the MESFET is limited to a maximum forward bias of 0.6V.

6. A circuit as recited in claim 1 where the maximum DC gate current is less than 1 mA.

7. A circuit as recited in claim 1 where the maximum DC gate current is less than 100 μA.

8. A circuit as recited in claim 1 where the source of the MESFET is biased at a fixed potential or ground.

9. A circuit as recited in claim 1 where the source of the MESFET varies or is not grounded and where the gate drive circuit is referenced to this moving source potential.

10. A gate drive circuit configured to drive the gate of an N-channel MESFET where the gate drive circuit limits the maximum forward biasing of the Schottky gate intrinsic to the MESFET to a predetermined maximum DC current level.

11. A circuit as recited in claim 10 where the MESFET is a normally off type.

12. A circuit as recited in claim 10 where the MESFET comprises GaAs.

13. A circuit as recited in claim 10 where the forward bias current of the Schottky gate intrinsic to the MESFET is limited to a maximum of 1 mA.

14. A circuit as recited in claim 10 where the forward bias current of the Schottky gate intrinsic to the MESFET is limited to a maximum of 100 μA.

15. A circuit as recited in claim 10 where the source of the MESFET is biased at a fixed potential or ground.

16. A circuit as recited in claim 10 where the source of the MESFET varies or is not grounded and where the gate drive circuit is referenced to this moving source potential.

17. A gate drive circuit configured to drive the gate of an N-channel MESFET where the gate drive circuit limits the maximum forward biasing of the Schottky gate intrinsic to the MESFET to a voltage less than the voltage powering the gate drive circuit.

18. A circuit as recited in claim 17 where the maximum MESFET gate drive is limited by a source follower connected N-channel MOSFET having a gate biased at some fixed potential, a drain biased at the voltage powering the gate drive circuit, and a source connected to the gate of the MESFET.

19. A circuit as recited in claim 18 where the bias potential is substantially equal to the sum of the threshold voltage of the MESFET and the threshold voltage of source-follower MOSFET.

20. A circuit as recited in claim 18 where the bias potential is less than 1.4 volts.

21. A circuit as recited in claim 17 where the maximum MESFET gate drive is limited by a linear regulator or low-drop-out linear regulator.

22. A circuit as recited in claim 21 where the maximum gate-to-source voltage of the MESFET is limited to a maximum of 0.7V.

23. A circuit as recited in claim 22 where the maximum gate-to-source voltage of the MESFET is determined by a resistor divider.

24. A circuit as recited in claim 17 where the maximum MESFET gate drive is limited by a resistor divider.

25. A circuit as recited in claim 24 where the resistor divider is powered from a CMOS inverter.

26. A circuit as recited in claim 17 where the maximum MESFET gate drive is limited by an NPN emitter follower.

27. A circuit as recited in claim 17 where the maximum MESFET gate drive is limited by a series of one or more forward biased PN junction diodes.

28. A circuit as recited in claim 27 where the forward diodes include parallel MOSFETs that shunt the diodes thereby varying the voltage drop between the battery and the MESFET gate in a dynamically controllable manner.

29. A gate drive circuit configured to drive the gate of an N-channel MESFET where the gate drive circuit limits the maximum forward biasing of the Schottky gate intrinsic to the MESFET to a maximum current.

30. A circuit as recited in claim 29 where a constant current source powered from the battery drives the gate of the MESFET in its on-state, and where an N-channel MOSFET drives the gate of the MESFET into an off condition by shorting its gate to its source.

31. A circuit as recited in claim 30 where the current source is in series with a battery connected switch that shuts off the current source whenever the N-channel MOSFET is on.

32. A circuit as recited in claim 30 where the current source comprises a P-channel current mirror.

33. A dynamic gate drive circuit driving the gate of an N-channel MESFET where the gate drive circuit dynamically limits the maximum forward biasing of the Schottky gate intrinsic to the MESFET to a maximum voltage using a circuit that requires constant and repeated switching to function.

34. A circuit as recited in claim 33 where the gate voltage is determined by a fixed capacitor voltage divider driven by a CMOS inverter.

35. A circuit as recited in claim 34 where a second N-channel is capable of driving the gate of the N-channel MESFET to its source potential, in order to rapidly turn off the N-channel MESFET.

36. A dynamic gate drive circuit driving the gate of an N-channel MESFET where the gate drive circuit limits the maximum forward biasing of the Schottky gate intrinsic to the MESFET to a maximum voltage by a switched capacitor network and a LDO regulator.

37. A circuit as recited in claim 36 where the switched capacitors are charged at the same frequency as the frequency the MESFET switching.

38. A circuit as recited in claim 36 where the switched capacitors are charged and recharged at a frequency higher than that of the MESFET switching.

39. A circuit as recited in claim 36 where the switched capacitor network decreases the voltage input to the LDO to some fraction of the battery or input voltage of the circuit.

40. A circuit as recited in claim 36 where the number of switched capacitors is two.

41. A circuit as recited in claim 36 where the number of switched capacitors is three or more.

42. A circuit as recited in claim 36 where the switches in the switched capacitor network comprise P-channel and N-channel MOSFETs.

43. A dynamic floating gate drive circuit for driving the gate of an N-channel MESFET where the source of the MESFET is not connected to ground, the floating gate drive comprising:
a bootstrap capacitor;
a bootstrap diode with its anode connected to an input voltage and with its cathode connected to the positive terminal of the bootstrap capacitor; and
a floating gate buffer driving the gate of the MESFET where the floating gate buffer is powered by the bootstrap capacitor and shares a common electrical node with the MESFET and the negative terminal of the bootstrap capacitor; where the gate buffer limits the maximum forward biasing of the Schottky gate intrinsic to the MESFET to a maximum gate to source voltage.

44. A circuit as recited in claim 43 where the common electrical node is repeatedly and temporarily connected to ground by some switch or transistor at some regular interval of varying frequency, and where the bootstrap capacitor is electrically charged during such intervals when the common electrical is grounded.

45. A circuit as recited in claim 43 where the gate buffer is limited in its output voltage by a source follower connected N-channel MOSFET having a gate biased at some fixed potential, a drain biased at the voltage of the positive bootstrap capacitor powering the floating gate drive circuit, and a source connected to the gate of the MESFET.

46. A circuit as recited in claim 45 where the bias potential is substantially equal to the sum of the threshold voltage of the MESFET and the threshold voltage of source-follower MOSFET.

47. A circuit as recited in claim 46 where the bias potential is less than 1.4 volts.

48. A circuit as recited in claim 43 where the gate buffer is limited in its output voltage by a resistor divider.

49. A circuit as recited in claim 48 where the resistor divider is powered from a CMOS inverter.

50. A circuit as recited in claim 43 where the gate buffer is limited in its output voltage by an LDO linear regulator.

51. A dynamic floating gate drive circuit for driving the gate of an N-channel MESFET whose source is not connected to ground, the floating gate drive comprising:
a bootstrap capacitor;
a bootstrap diode with its anode connected to an input voltage and with its cathode connected to the positive terminal of the bootstrap capacitor; and
a floating gate buffer driving the gate of the MESFET where the floating gate buffer is powered by the bootstrap capacitor and shares a common electrical node with the MESFET and negative terminal of the bootstrap capacitor; where the gate buffer limits the maximum forward biasing of the Schottky gate intrinsic to the MESFET to a maximum gate to a maximum current.

52. A circuit as recited in claim 51 where a constant current source powered from the bootstrap capacitor drives the gate of the MESFET in its on-state, and where an N-channel MOSFET drives the gate of the MESFET into an off condition by shorting its gate to its source.

53. A circuit as recited in claim 52 where the current source shuts off whenever the N-channel MOSFET is on.

54. A dynamic floating gate drive circuit for driving the gate of an N-channel MESFET whose source is not connected to ground, the floating gate drive comprising:
a bootstrap capacitor;
a bootstrap diode with its anode connected to an input voltage via a capacitor charge limiting circuit and with its cathode connected to the positive terminal of the bootstrap capacitor; and
a floating gate buffer driving the gate of the MESFET where the floating gate buffer is powered by the bootstrap capacitor and shares a common electrical node with the MESFET and negative terminal of the bootstrap capacitor.

55. A circuit as recited in claim 54 where the gate buffer limits the maximum forward biasing of the Schottky gate intrinsic to the MESFET to a maximum gate to source voltage.

56. A circuit as recited in claim 64 where the gate buffer limits the maximum forward biasing of the Schottky gate intrinsic to the MESFET to a maximum current.

57. A circuit as recited in claim 54 where the capacitor charge limiting circuit limits the fully charged voltage on the bootstrap capacitor to a voltage less than the battery or input voltage.

58. A circuit as recited in claim 54 where the capacitor charge limiting circuit comprises a LDO linear regulator.

59. A circuit as recited in claim 54 where the capacitor charge limiting circuit comprises a number of series-connected forward biased PN diodes.

60. A circuit as recited in claim 59 where the forward diodes include parallel MOSFETs that shunt the diodes thereby varying the voltage drop between the battery and the bootstrap capacitor in a dynamically controllable manner.

61. A circuit as recited in claim 54 where the capacitor charge limiting circuit comprises a current source.

62. A circuit as recited in claim 61 where the current source is controlled by a comparator monitoring the bootstrap capacitor voltage, where the current source is switched off when the bootstrap capacitor voltage exceeds some reference voltage.

63. A circuit as recited in claim 54 where the capacitor charge limiting circuit comprises a switched capacitor network.

64. A DC-to-DC converter comprising series-connected low-side and high-side MESFETs where:
the low-side MESFET is powered by a low-side gate drive circuit that limits the maximum forward biasing of the Schottky gate intrinsic to the low side MESFET to a maximum voltage or maximum current;
where the low-side gate drive circuit is ground referenced;
the low-side gate drive circuit is powered from the battery; and where
the high-side MESFET is powered by a floating gate drive circuit that limits the maximum forward biasing of the Schottky gate intrinsic to the high side MESFET to a maximum voltage or maximum current; where
the high-side gate drive circuit is referenced to the source of the high-side MESFET and to the drain of the low-side MESFET;
the high-side gate drive circuit is powered from a bootstrap capacitor charged through a bootstrap diode.

65. A circuit as recited in claim 64 where the bootstrap capacitor is charged to a voltage less than the battery voltage.

66. A DC-to-DC converter comprising series-connected low-side and floating MESFETs where:
the low-side MESFET is powered by a low-side gate drive circuit that limits the maximum forward biasing of the Schottky gate intrinsic to the low-side MESFET to a maximum voltage or maximum current; where
the low-side gate drive circuit is ground referenced;
the low-side gate drive circuit is powered from the battery; and where
the floating-side MESFET is powered by a floating gate drive circuit that limits the maximum forward biasing of the Schottky gate intrinsic to the floating-side MESFET to a maximum voltage or maximum current; where
the floating gate drive circuit is referenced to the source of the floating-side MESFET whenever the floating-side MESFET is on;
the floating gate drive circuit is powered from a bootstrap capacitor charged through a bootstrap diode; and
the floating drive circuit and bootstrap capacitor are referenced to ground whenever the floating side MESFET is not on.

67. A circuit as recited in claim 66 where the bootstrap capacitor is charged to a voltage less than the battery voltage.
